(19) United States
(12) Patent Application Publication
(10) Pub. No.: US 2005/0189015 A1
(43) Pub. Date: Sep. 1, 2005

(54) Silicon solar cells and methods of fabrication

(76) Inventors: Ajeet Rohatgi, Marietta, GA (US); Ji-Weon Jeong, Daejun (KR); Kenta Nakayashiki, Smyrna, GA (US); Vijay Yelundur, Woodstock, GA (US); Dong Seop Kim, Seoul-Si (KR); Mohamed Hilali, Atlanta, GA (US)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/977,751

(22) Filed: Oct. 29, 2004

Related U.S. Application Data
(60) Provisional application No. 60/515,780, filed on Oct. 30, 2003.
(60) Provisional application No. 60/526,919, filed on Dec. 5, 2003.

(51) Int. Cl. H01L 31/00

(52) U.S. Cl. 136/261; 136/252

(57) ABSTRACT

Devices, solar cell structures, and methods of fabrication thereof, are disclosed. Briefly described, one exemplary embodiment of the device, among others, includes: a co-fired p-type silicon substrate, wherein the bulk lifetime is about 20 to 125 μs; an n⁺ layer formed on the top-side of the p-silicon substrate; a silicon nitride anti-reflective (AR) layer positioned on the top-side of the n⁺ layer; a plurality of Ag contacts positioned on portions of the silicon nitride AR layer, wherein the Ag contacts are in electronic communication with the n⁺-type emitter layer; an uniform Al back-surface field (BSF or p⁺) layer positioned on the back-side of the p-silicon substrate on the opposite side of the p-type silicon substrate as the n⁺ layer; and an Al contact layer positioned on the back-side of the Al BSF layer. The device has a fill factor (FF) of about 0.75 to 0.85, an open circuit voltage (V_{OC}) of about 600 to 650 mV, and a short circuit current (J_{SC}) of about 28 to 36 mA/cm².

### CROSS-REFERENCE TO RELATED APPLICATIONS

This application claims priority to co-pending U.S. provisional application entitled, “Development of Good Ohmic Contacts for High Efficiency to High-Sheet-Resistance Emitters for Silicon Solar Cells,” having Ser. No. 60/515,780, filed Oct. 30, 2003, and co-pending U.S. provisional application entitled, “Rapid Firing Enhance AI-BSF, Contacts and SiN Induced Hydrogenation Design and Development of 18-20% Efficient Czochraski Monocrystalline Si,” having Ser. No. 60/526,919, filed Nov. 24, 2003, both of which are entirely incorporated herein by reference.

### TECHNICAL FIELD OF THE INVENTION(S)

The present disclosure is generally related to solar cells and, more particularly, embodiments of the present disclosure are related to silicon solar cells and methods of fabricating of silicon solar cells.

### BACKGROUND

For many years, effort has been made to utilize the energy from the sun to produce electricity. It is well known that on a clear day the sun provides approximately one thousand watts of energy per square meter almost everywhere on the planet's surface. The historical intention has been to collect this energy by using, for example, an appropriate solar semiconductor device and utilizing the collected energy to produce power by the creation of a suitable voltage and to maximize amperage, which is represented by the flow of electrons. However, to date, many photovoltaic or solar cells typically have low overall efficiency.

The success of the solar cell industry has been impeded due to this lack of efficiency in solar cell fabrication and usage. For example, it is relatively expensive to manufacture the semiconductor materials currently utilized for solar cells and applicable processes. One traditional approach for manufacturing solar cells has included converting low quality silicon wafers from the semiconductor industry into solar cells by known techniques, which include etching of the wafers and subsequent processing of the silicon wafers so that they can function as solar cells. A second technique includes creating relatively thin layers of crystalline and/or amorphous silicon upon an appropriate substrate followed by processing techniques, which ultimately result in the production of a solar cell/solar panel. However, the extensive processes used in the above described approaches have historically been relatively inefficient, making the solar cell industry less than ideal.

Thus, a heretofore unaddressed need exists in the solar cell industry for solar cells and processes for fabricating the solar cells that address the aforementioned deficiencies and/or inadequacies.

### SUMMARY

Devices, solar cell structures, and methods of fabrication thereof, are disclosed. Briefly described, one exemplary embodiment of the device, among others, includes: a co-fired p-type silicon substrate, wherein the bulk lifetime is about 20 to 125 μs; an n⁺ layer (emitter) formed on the top-side of the p-silicon substrate; a silicon nitride anti-reflective (AR) layer positioned on the top-side of the n⁺ layer; a plurality of Ag contacts positioned on portions of the silicon nitride AR layer, wherein the Ag contacts are in electronic communication with the n⁺ layer; an uniform Al back-surface field (BSF or p⁺) layer positioned on the back-side of the p-silicon substrate on the opposite side of the p-type silicon substrate as the n⁺-type emitter layer; and an Al contact layer positioned on the back-side of the Al BSF layer. The device has a fill factor (FF) of about 0.75 to 0.85, an open circuit voltage (V_{OC}) of about 600 to 650 mV, and a short circuit current density (J_{SC}) of about 28 to 36 mA/cm².

Briefly described, one exemplary embodiment of the solar cell structure includes: a co-fired p-type silicon substrate, wherein the bulk lifetime is about 75 to 125 μs; a n⁺-type emitter layer formed on the top-side of the p-silicon substrate, wherein the n⁺-type emitter is about 90 to 120 Ω/sq emitter; a silicon nitride anti-reflective (AR) layer positioned on the top-side of the n⁺-type emitter layer; a plurality of Ag contacts positioned on portions of the silicon nitride AR layer, wherein the Ag contacts are in electronic communication with the n⁺-type emitter layer; an Al back surface field (BSF) layer positioned on the back-side of the co-fired p-silicon substrate on the opposite side of the p-type silicon substrate as the n⁺-type emitter layer; and an Al contact layer positioned on the back-side of the Al back-surface field (BSF) layer. The solar cell has a fill factor (FF) of about 0.78 to 0.81, an open circuit voltage (V_{OC}) of about 640 to 650 mV, a short circuit current density (J_{SC}) of about 34 to 36 mA/cm², a series resistance (R_{S}) of about 0.8 to 1 Ω-cm², a shunt resistance of about 1000 to 2000 kΩ, a junction leakage current of about 7 to 10 nA/cm², and a back surface recombinant velocity (BSRV) of about 200 to 900 cm/s, and wherein the contact resistance (ρ_{C}) of the Ag contacts with the n⁺-type emitter layer is about 1.5 to 2 Ωcm².

Briefly described, one exemplary embodiment of a method for fabricating a silicon solar cell structure includes: providing a p-silicon substrate having a top-side and a back-side; forming a n⁺-type emitter layer on the top-side of the p-silicon substrate; forming a silicon nitride anti-reflective (AR) layer on the top-side of the n⁺-type emitter layer; forming Ag contacts on the silicon nitride anti-reflective (AR) layer using a screen-printing technique; forming an Al contact layer on the back-side of the p-silicon substrate using a screen-printing technique; co-firing of the p-silicon substrate having the n⁺-type emitter layer, silicon nitride anti-reflective (AR) layer, Ag metal contacts, and Al contact layer; and forming a co-fired silicon solar cell structure. The Ag contacts are in electrical communication with the n⁺-type emitter layer. An Al back surface field layer (BSF) is formed, and the silicon solar cell has a fill factor of about 0.75 to 0.85, a V_{OC} of about 550 to 650 mV, and a J_{SC} of about 28 to 36 mA/cm².

Briefly described, one exemplary embodiment of a method for co-firing a silicon solar cell includes: providing a silicon solar cell structure as described above; disposing the p-silicon substrate having the n⁺-type emitter layer, silicon nitride anti-reflective (AR) layer, Ag metal grid, and Al contact layer, into a belt furnace; heating the belt furnace at a rate of about 50 to 100° C./second to a temperature of about 700 to 900° C.; holding the temperature in the belt furnace at about 700 to 900° C. for about 1 to 5 seconds; and reducing the temperature in the belt furnace at a rate of about 50 to 100° C./second.

Other systems, methods, features, and advantages of the present invention will be or become apparent to one with skill in the art upon examination of the following drawings and detailed description. It is intended that all such additional systems, methods, features, and advantages be included within this description, be within the scope of the present invention, and be protected by the accompanying claims.

### BRIEF DESCRIPTION OF THE DRAWINGS

Many aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 illustrates an exemplary embodiment of a silicon solar cell structure.

FIG. 2 illustrates a flowchart describing an exemplary method of forming the silicon solar cell structure shown in FIG. 1.

FIG. 3 illustrates a flowchart describing an exemplary method of the rapid co-firing process described in FIG. 2.

FIGS. 4A through 4F illustrate an exemplary method of forming the silicon solar cell structure shown in FIG. 1.

FIG. 5 is an exemplary graph illustrating the contact resistance values for conventional pastes (A and B) on 40 and 100 Ohm (Ω)/sq. emitters.

FIG. 6 is an exemplary graph illustrating the contact resistance values for PV 168 on emitters of different sheet resistance.

FIG. 7 is an exemplary graph illustrating the series resistance and fill factor (FF) as a function of emitter sheet resistance.

FIG. 8 is an exemplary graph illustrating the IQE plots for the conventional paste 2-step fired cell on a 40 Ω/sq. emitter and the selective-emitter cell using PV168 on a 100 Ω/sq. emitter.

FIG. 9 is an exemplary graph illustrating spreading resistance profiles of POCl₃ diffused 100 Ω/sq. and 45 Ω/sq. emitters

FIG. 10 is an exemplary graph illustrating specific contact resistance values for pastes A and B on 45 and 100 Ω/sq. emitters using the optimum firing conditions used for conventional cells for each paste.

FIG. 11A is an exemplary graph illustrating V_{oc} of cells with grid metallization using pastes A and B on 45 and 100 Ω/sq. emitters using the optimum firing conditions for conventional cells (45 Ω/sq.).

FIG. 11B is an exemplary graph illustrating J₀₂ values for pastes A and B on 45 and 100 Ω/sq. emitters using the optimum firing conditions for each paste.

FIG. 12 is an exemplary graph illustrating the effect of firing set temperature on specific contact resistance (mΩ-cm²), series resistance (mΩ-cm²), and fill factor for 100 Ω/sq. emitter.

FIG. 13 is an exemplary graph illustrating the effect of belt speed on J₀₂ (nA/cm²), V_{oc} (mV), and the FF for 100 Ω/sq. emitters.

FIG. 14 is an exemplary graph illustrating SIMS profiles for the 100 Ω/sq. emitter, and for PV168 Ag fired at different belt speeds.

FIG. 15 is an exemplary graph illustrating a comparison of specific contact resistance (mΩ-cm²), open-circuit voltage (mV), junction leakage current (nA/cm²), and Ag concentration at the junction (cm⁻³) for pastes PV168, A, and B for the same co-firing condition of 900° C./80 ipm.

FIG. 16 is an exemplary graph illustrating IQE plots for a conventional 2-step fired cell and a 45 Ω/sq. emitter using paste A and the PV168 paste co-fired cells on a 100 Ω/sq. emitter with high-frequency silicon nitride passivation.

FIG. 17 is an exemplary graph illustrating the change in V_{oc} (ΔV_{oc}) for 100 Ω/sq. emitter as compared to a 45 Ω/sq.-emitter cell as a function of FSRV (left axis). Change in short-circuit current (ΔJ_{sc}) and efficiency ((Δη) as compared to a 45 Ω/sq.-emitter cell as a function of FSRV (left axis). The FSRV for 45 Ω/sq.-emitter cell was set to 200,000 cm/s.

FIG. 18 is an exemplary graph illustrating IQE plots for the PV168 paste co-fired cells on a 100 Ω/sq. emitter with low-frequency Si₃N₄ passivation and the conventional 2-step fired cell with a 45 Ω/sq., 100 Ω/sq. emitter and high-frequency Si₃N₄ passivation.

FIG. 19 is an exemplary graph illustrating V_{oc} as a function of FSRV on 100 Ω/sq. emitter (left axis), where the change in V_{oc} (ΔV_{oc}) for 100 Ω/sq. emitter as compared to a 45 Ω/sq. emitter cell as a function of FSRV (right axis).

FIG. 20 is an exemplary graph illustrating the measured J_{oc} using PCD technique on different passivating dielectrics.

FIG. 21 is an exemplary graph illustrating the measured V_{oc} of solar cells with different passivating dielectrics.

FIG. 22 is an exemplary graph illustrating the short-wavelength IQE response of solar cells with different passivating dielectrics.

FIG. 23 illustrates three exemplary images, where (a) is as-dried screen-printed PV168 Ag paste gridline, (b) is PV168 gridline after alloying at a set temperature ≧900° C., and (c) is conventional paste-A fired at about 750° C. (note width is in micrometers).

FIG. 24 is an exemplary graph illustrating the IQE response for the 45 Ω/sq. and 100 Ω/sq. emitter solar cells with LF-silicon nitride and stack RTO/LF-silicon nitride passivation.

FIG. 25 is an exemplary graph illustrating the efficiency progress of silicon ribbon solar cells.

FIG. 26 is an exemplary graph illustrating I-V data for the record high 16.1% efficient screen-printed EFG solar cell, verified by NREL.

FIG. 27 is an exemplary graph illustrating the IQE analysis of EFG solar cell with 95 Ω/sq. and 45 Ω/sq. emitters.

FIG. 28 is an exemplary graph illustrating cell data of record high efficiency (16.9%) screen-printed HEM mc-Si cell, verified by NREL, and a comparison of IQE of HEM cells with low- and high-frequency silicon nitride.

FIG. 29 is an exemplary graph illustrating the progress in efficiency of laboratory scale ribbon solar cells with photolithography contacts.

FIGS. 30A and 30B is an exemplary graph illustrating the process induced lifetime enhancement in String Ribbon (FIG. 30A) and EFG Si (FIG. 30B). Lifetime is shown as a function of P-diffusion and silicon nitride/Al co-firing at different condition.

FIGS. 31A and 31B are exemplary graphs illustrating light I-V characteristics of ribbon silicon solar cells on String Ribbon (FIG. 30A) and EFG (FIG. 30B) measured by NREL.

FIG. 32 is an exemplary graph illustrating the progress in efficiency of laboratory scale ribbon solar cells.

FIG. 33 is an exemplary graph illustrating the efficiencies as a function of firing temperature and time for Al-BSF.

FIG. 34 is an exemplary graph illustrating the effects of each process steps on the lifetime of String Ribbon.

FIG. 35 is an exemplary graph illustrating the V_{oc} as a function of firing temperature and time. PL contact cells were fabricated on 2 Ωcm FZ with rapid thermal oxide for emitter passivation and ZnS/MgF₂ for antireflection coating.

FIG. 36 is an exemplary graph illustrating the IQE responses for different firing processes.

FIG. 37 is an exemplary graph illustrating the cross-section SEM micrographs of the Al-BSF region for different firing processes.

FIG. 38 is an exemplary graph illustrating Al-BSF thicknesses and effective surface recombination velocities measured by SEM and calculated based on the Al—Si phase diagram.

FIG. 39 is an exemplary flow diagram illustrating an embodiment of a process used in Example 7.

FIG. 40 is an exemplary graph illustrating an open-circuit voltage of FZ Si cells as a function of firing time in the range of 1 to 60 second (s).

FIG. 41 is an exemplary graph illustrating the internal quantum efficiency of FZ Si cells as a function of firing time ranging from 1-60 s.

FIG. 42 illustrates two exemplary cross-sectional SEM pictures of the Al-BSF region in FZ Si cells fabricated with (a) 1 s firing and (b) 60 s firing.

FIG. 43 is an exemplary graph illustrating open-circuit voltages of EFG Si cells as a function of Al-BSF firing time.

FIG. 44 is an exemplary graph illustrating the average minority carrier lifetime in EFG wafers as a function of Al-BSF firing time.

FIG. 45 are exemplary graphs illustrating cross-sectional SEM pictures of the Al-BSF region in EFG Si cells fabricated with (a) 1 s firing and (b) 60 s firing.

FIG. 46 is an exemplary graph illustrating device simulation results to map the efficiency-dependence of minority carrier lifetime and BSRV for screen-printed cells.

### DETAILED DESCRIPTION

In accordance with the purposes(s) of the present disclosure, as embodied and broadly described herein, embodiments of the present disclosure, in one aspect, relate to silicon solar cell structures and methods of fabricating silicon solar cell structure.

In general, embodiments of the silicon (Si) solar cell structure include, but are not limited to, a p-silicon substrate, a n⁺-type emitter layer formed on the top-side (i.e., top, front, and front-side of the p-silicon substrate) of the p-silicon substrate, a silicon nitride (e.g., SiNₓ) antireflection (AR) layer positioned on the top-side of the n⁺-type emitter layer, a plurality of silver (Ag) contacts (which are part of an Ag grid) positioned on portions of the SiNₓ antireflective layer, an aluminum (Al) back-surface field (BSF) layer positioned on the back-side (i.e., back, rear, and rear-side of the p-silicon substrate) of the p-silicon substrate (i.e., the side opposite the n⁺-type emitter layer), and an Al contact layer positioned on the back-side of the Al BSF. The Ag contacts are in electronically connected to the n⁺-type emitter layer.

In general, embodiments of the fabrication of silicon solar cell structure include processes that result in a silicon solar cell structure having unexpected characteristics such as, but not limited to, superior ohmic contact, superior solar cell performance and efficiency, high quality front and back screen printed contacts that can be rapidly produced, increased throughput of a manufacturing line, superior Al back-surface field (BSF), reduced cell processing time and firing steps, and superior surface passivation and maximization of the defect hydrogenation and solar cell bulk lifetime, as compared with other solar cells.

In particular, embodiments of the silicon solar cell structure have unexpected characteristics such as, but not limited to, superior fill factor (FF), superior open circuit voltage (V_{OC}), and superior short circuit current density (J_{SC}). In addition, embodiments of the silicon solar cell structure have additional characteristics such as, but not limited to, superior blue response, superior series resistance (R_{S}), superior shunt resistance, superior junction leakage current density (J_{O2}), superior bulk lifetime, superior back-surface field, superior emitter saturation current density (Jₒₑ), superior base saturation current density (J_{ob}), superior grid design, gridline width, and gridline shrinkage, and final metal gridline resistivity, as compared with other solar cells.

The silicon solar cell structure can be used, individually or in combination, in solar cells modules. The silicon solar cells modules incorporating one or more silicon solar cell structures can be used in many areas such as, but not limited to, orbiting space satellites, remote telecommunication repeaters, fiber optic amplifiers, remote street signs, telephone booths, outdoor lighting, homes, utility scale power generation, and the like.

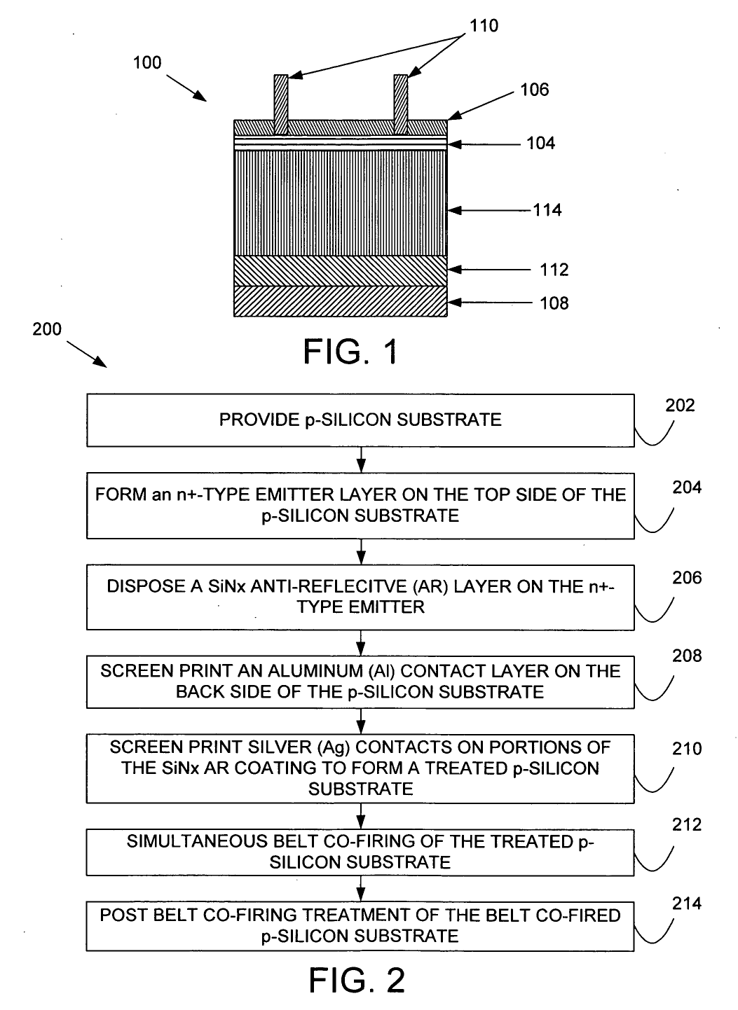

Now having described embodiments of the silicon solar cell structure and methods of making the silicon solar cell structure in general, the following figures and the accompanying text describe various embodiments in greater detail. FIG. 1 illustrates an exemplary embodiment of a screen-printed contact co-fired silicon solar cell structure 100 (e.g, after co-firing of the metal screen-printed metal contacts process) (hereinafter “co-fired silicon solar cell structure 100”). The co-fired silicon solar cell structure 100 includes, but is not limited to, a treated p-silicon substrate 114 having a top-side and a back-side, a n⁺-type emitter layer 104 formed on the top-side of the treated p-silicon substrate 114, a silicon nitride (SiNₓ) anti-reflective (AR) layer 106 positioned on the top-side of the n⁺-type emitter layer 104, a plurality of Ag contacts 110 (part of the Ag grid, where only the Ag contacts are shown) positioned on portions of the SiNₓ AR coating 106, an Al back-surface field layer 112 (formed after the metal co-firing process) positioned on the back-side of the treated p-silicon substrate 114, and an Al contact layer 108 positioned on the back-side of the Al back-surface field layer 112. The term “plurality” as used herein can be construed to mean two or more, as well as a multitude or numerous.

As mentioned above, the p-silicon substrate can include, but is not limited to, edge-defined film fed grown (EFG) silicon wafer, string ribbon silicon, float zone (FZ) silicon, Czochralski (Cz) grown silicon, and cast multi-crystalline silicon (mc-Si). Due to the treatment processes described herein, the p-silicon substrate initially used (not shown in FIG. 1) can be of lower quality. The p-silicon substrate can have a thickness of about 450 to 650 μm, about 350 to 500 μm, and about 150 to 300 μm.

The process of forming the n⁺-type emitter layer, which is known as gettering, and metal contact co-firing involve diffusion of hydrogen from the silicon nitride (SiNₓ) into the p-silicon substrate to passivate the defects sites (e.g., hydrogenation). A combination of these processes, in part, improves the quality of low quality p-silicon substrate materials (e.g., materials having lifetime of about 0.5 μs). However, good quality p-silicon substrate material (e.g., materials having lifetimes of more than about 150 μs) does not benefit from the hydrogenation.

The n⁺-type emitter layer can include, but is not limited to, about 55 to 120 Ω/sq emitter, about 60 to 120 Ω/sq emitter, about 65 to 120 Ω/sq emitter, about 70 to 120 Ω/sq emitter, about 75 to 120 Ω/sq emitter, about 80 to 120 f/sq emitter, about 85 to 120 Ω/sq emitter, about 90 to 120 Ω/sq emitter, about 95 to 120 Ω/sq emitter, about 100 to 120 Ω/sq emitter, about 105 to 120 Ω/sq emitter, about 110 to 120 Ω/sq emitter, about 115 to 120 Ω/sq emitter, 55 to 100 Ω/sq emitter, about 60 to 100 Ω/sq emitter, about 65 to 100 Ω/sq emitter, about 70 to 100 Ω/sq emitter, about 75 to 100 Ω/sq emitter, about 80 to 100 Ω/sq emitter, about 85 to 100 Ω/sq emitter, about 90 to 100 Ω/sq emitter, and about 95 to 100 Ω/sq emitter. In particular, the n⁺-type emitter layer can include, but is not limited to, about 55 Ω/sq emitter, about 60 Ω/sq emitter, about 65 Ω/sq emitter, about 70 Ω/sq emitter, about 75 Ω/sq emitter, about 80 Ω/sq emitter, about 85 Ω/sq emitter, about 90 Ω/sq emitter, about 95 Ω/sq emitter, and about 100 Ω/sq emitter. The n⁺-type emitter layer can have a thickness of about 0.2 cm to 0.7 μm and about 0.3 μm to 0.5 cm.

The silicon nitride (e.g, SiNₓ) anti-reflective (AR) layer can be described as a film, coating, and layer. Although, the stoichiometry of the SiNₓ is not fully understood, an estimate of the value of “x” can be from about 2 to 5. The SiNₓ anti-reflective (AR) layer can have a thickness of about 700 to 850 Å, about 750 to 850 Å, and about 780 to 800 Å.

The Al contact layer 108 can have a thickness of about 50 to 60 μm, about 30 to 50 μm, and about 15 to 20 μm. It should be noted that the Al contact layer 108 thickness depends, at least in part, on the thickness of the p-silicon substrate used. It also should be noted that a thicker Al contact layer 108 can cause warping of thin p-silicon substrates, which can be detrimental to module assembly and the like.

The Al back-surface field layer 112 should have a uniform BSF, which can be accomplished using the co-firing process described herein. The Al back-surface field layer 112 can have a thickness of about 2 μm to 40 μm, about 2 μm to 30 μm, about 2 μm to 20 μm, about 2 μm to 15 μm, about 2 μm to 10 μm, and about 5 μm to 10 μm.

As indicated above, the co-fired silicon solar cell structure can have characteristics such as, but not limited to, a fill factor (FF) of about 0.75 to 0.85, about 0.78 to 0.83, and about 0.78 to 0.81. The co-fired silicon solar cell can have an open circuit voltage (V_{OC}) of about 550 to 660 mV, about 600 to 660 mV, about 640 to 660 mV, and about 645 to 660 mV. The co-fired silicon solar cell structure can have a short circuit current density (J_{SC}) of about 28 to 39 mA/cm², about 30 to 39 mA/cm², about 34 to 39 mA/cm² and 36 to 39 mA/cm².

Further, the co-fired silicon solar cell structure can include characteristics such as, but not limited to, a bulk lifetime of about 20 to 400 μs, about 50 to 400 μs, and about 75 to 400 μs. The co-fired silicon solar cell structure can include a series resistance (R_{S}) of about 0.01 to 1 Ω-cm², about 0.50 to 1 Ω-cm², and about 0.80 to 1 Ω-cm². The co-fired silicon solar structure can include a shunt resistance of about 1000 to 5000 kΩ-cm², about 1000 to 3500 kΩ-cm², and about 1000 to 2000 kΩ-cm². The co-fired solar silicon cell structure can include a junction leakage current density (J_{O2}) of about 1 to 10 nA/cm², about 4 to 10 nA/cm², and about 7 to 10 nA/cm². The co-fired silicon solar cell structure can include a contact resistance (ρ_{C}) of 0.01 to 3 mΩ-cm², about 1 to 3 mΩ-c cm², and about 1.5 to 3 mΩ-cm². The co-fired silicon solar cell structure can include a back surface recombination velocity (BSRV) of about 200 to 1000 cm/s, about 400 to 1000 cm/s, and about 600 to 900 cm/s, but is should be noted this depends, in part, on the substrate resistivity.

It should be noted that the FF of the co-fired silicon solar cell structure is related, at least in part, to the series resistance (R_{S}), the shunt resistance, and the junction leakage current density (J_{O2}). In an embodiment, after co-firing, the co-fired silicon solar cell structure has a R_{S} of about 0.80 to 1 Ω-cm², a shunt resistance of about 1000 to 2000 kΩ, and a I_{O2} of about 7 to 10 nA/cm², which indicate excellent ohmic contact and thus an excellent FF of 0.78 to 0.81. The co-firing process results in a co-fired silicon solar cell structure with a reduction in junction leakage current, and a decrease in junction leakage current produces increased J_{SC} and an increased V_{OC}. Unexpected silicon solar cell structure characteristics are a result of the co-firing process described herein. For example, hydrogen is transferred from the SiNₓ layer to the p-silicon substrate where it is retained in the defects (a process called defect passivation) of the solar cell structure. It should be noted that deviation (e.g., longer holding times) from the co-firing process can drive the hydrogen out of the p-silicon substrate, therefore, appropriate selection of process parameters can enhance the characteristics of the silicon solar cell structure. In this regard, increased defect passivation results in a co-fired silicon solar cell structure with increased bulk lifetime and increased solar cell efficiency. In another example, the co-fired silicon solar cell structure also includes an Al back surface field with increased uniformity due, at least in part, to uniform surface wetting with fast ramp-up. It should also be noted, that the excellent BSRV obtained is due, at least in part, to a uniform Al back-surface field layer.

In one embodiment, among others, the co-fired silicon solar cell structure can have characteristics such as, but not limited to, a fill factor (FF) of about 0.78 to 0.81, an open circuit voltage (V_{OC}) of about 640 to 650 mV, and a short circuit current density (J_{SC}) of about 34 to 36 mA/cm². Further, the silicon solar cell structure can include a bulk lifetime of 75 to 400 μs, a series resistance (R_{S}) of about 0.5 to 1 Ω-cm², a shunt resistance of about 1000 to 2000 kΩ, a junction leakage current density (J_{O2}) of about 7 to 10 nA/cm², and a back surface recombination velocity (BSRV) of about 200 to 900 cm/s.

In general, the silicon solar cell structure, prior to co-firing, can be introduced to a belt furnace (described in more detail in Examples 1-8). For clarity, not every step in the process is shown, but one skilled in the art would understand additional steps that may need to be performed. In addition, the steps involved in the process can be performed in different orders, but in general, a p-silicon (p-Si) substrate is provided. An n⁺-type emitter layer is formed on the top-side of the p-silicon substrate. Then, a SiNₓ anti-reflective (AR) layer is positioned on the top-side of the n⁺-type emitter layer. Next, an aluminum (Al) contact layer 108 is screen printed on the back-side of the p-silicon substrate using an Al paste and dried at a temperature (e.g., about 190 to 220° C.). Subsequently, an Ag contact (e.g., part of an Ag metal grid (not shown)) is screen-printed on the top-side of the SiNₓ anti-reflective (AR) layer 106 using an Ag paste (e.g., PV168 Ag paste) and is dried at a temperature (e.g., about 190 to 220° C.). After the Ag contacts and Al contacts are formed, the structure is subjected to a co-firing process in the belt furnace under conditions described in more detail below, but include a temperature ramp up stage, a temperature holding stage, and a temperature ramp down stage. Post co-firing treatments can also be conducted to complete the silicon solar cell formation process.

FIG. 2 illustrates a flowchart 200 describing a representational method of the fabrication process for the silicon solar cell structure 100 shown in FIG. 1. In Block 202 an untreated p-silicon substrate having a top-side and a back-side is provided. The p-silicon substrate can include substrates such as, but not limited to, a Si wafer, EFG Si ribbon, string Si ribbon, FZ Si, Cz Si and cast mc-Si.

In Block 204, a n⁺-type emitter layer is formed on the top-side of the p-silicon substrate. The n⁺-type emitter can include n⁺-type emitters as described above. In forming the n⁺-type emitter layer, the p-silicon substrate samples can be cleaned and diffused using a liquid POCl₃ source in a tube furnace, for example. Spin-on, print-on, and spray-on phosphorus as well as and drive-in (at set temperatures depending on the required emitter sheet resistances) in a belt-furnace, a RTP, or a tube furnace. In Block 206, a SiNₓ antireflection (AR) layer 106 is positioned on the n⁺-type emitter. This process includes, but is not limited to, a pretreatment of ammonia plasma in-situ followed by the positioning of a low frequency (e.g., about 50 to 100 kHz) SiNₓ layer at about 400 to 450° C. in a direct plasma enhanced chemical vapor depostion (PECVD) SiNₓ reactor at about 750 to 800 A. Further, NH₃ and SiH₄ gases are present in the PECVD reactor and react to form the SiNₓ layer. Additional methods include direct PECVD (13.6 MHz) or remote PECVD (2.45 GHz) performed at temperatures between 350-450° C., for example. As a result, a large source of atomic hydrogen is created not only in the SiNₓ layer but also in a very thin Si layer underneath the SiNₓ layer. This is a result of high-energy ion bombardment, due to the low frequency SiNₓ positioning. In another embodiment, another material (e.g., MgF) can also be used to coat the SiNₓ antireflection (AR) layer to form a double layer AR coating.

In Block 208, aluminum (Al) contacts are screen-printed on the back-side of the p-silicon substrate. The aluminum contact can be positioned using, but not limited to, an Al paste which can be disposed using techniques such as, but not limited to, a process in which Al paste is screen printed on the back of the p-silicon substrate and dried at about 190 to 220° C. to form the Al contact layer on the back-side of the p-silicon substrate. The Al paste can include, but is not limited to FX53-038, and FX53-100.

In Block 210, Ag contacts, are positioned on portions of the SiNₓ layer using an Ag paste such as, but not limited to, PV168 paste (produced by DuPont) Ferro 3455 and Ferro 3460. The Ag contact can be positioned using techniques such as, but not limited to, a process in which Ag paste is screen-printed on the top-side of the SiNₓ AR layer. It should also be noted that photolithography and laser grooved techniques can be used to provide front metal contacts to silicon solar cells.

In Block 212, a rapid belt co-firing process can be used to treat the silicon solar cell structure 100. The co-firing process occurs after the positioning of the above described elements including, but not limited to, the p-silicon substrate, the n⁺-type emitter on the top-side of the p-silicon substrate, the SiNₓ AR layer on the top-side of the n⁺-type emitter, the Al contact on the back-side of the p-silicon substrate, the Ag contacts on the top-side of the SiNₓ AR layer.

The rapid co-firing process involves a simultaneous firing process. The co-firing process includes a temperature ramp up process. The ramp up process is performed at a ramp up rate of about 50 to 100° C./s, about 50 to 80° C./s, and about 50 to 60° C./s to reach the temperature of about 700 to 900° C., about 750 to 850° C., and about 740 to 780° C. Then, the co-firing process includes a temperature holding stage. In the temperature holding phase, the firing and hold time is about 1 to 5 seconds, about 1 to 3 seconds, and about 1 to 2 seconds, each at a temperature of about 700 to 900° C., about 750 to 850° C., and about 740 to 780° C. The shorter holding time results in maximum lifetime enhancement due to the higher retention of the hydrogen in the defect sites. Then, the co-firing process includes a ramp down stage. The ramp down stage includes reducing the temperature according to a ramp down rate of about 50 to 100° C./s, about 50 to 80° C./s, and about 50 to 60° C./s.

The rapid co-firing process is controlled, in part, by the belt speed and temperature setting in each zone of the belt furnace. The temperature in each zone or stage and the belt speed can each be set to achieve the temperature parameters described above. For example, the belt speed can be about 15 to 100 inches per minute (ipm), 50 to 100 ipm, 80 to 100 ipm and 100 to 120 ipm.

Although not intending to be bound by theory, the co-firing process described above, and the way in which the process is conducted, provide unexpected results. For example, the co-firing temperature and time exposed to the temperature allow for the simultaneous formation of front Ag contacts 110 and Al back-surface field 112 (p⁺ layer). Specifically, the co-firing steps result in the formation of a uniform back-surface field (BSF) 112 (or p⁺ layer) on the back-side of the co-fired solar cell structure 114. The co-firing process results in the etching of the SiNₓ by the glass frit contained in the Ag contacts to form a contact with the n⁺-type emitter layer, which allows n⁺-type emitter layer of higher sheet resistance values to be used (as described above). Further, the co-firing process produces a solar cell structure with unexpected characteristics such as, but not limited to, an increased defect passivation (in low quality silicon substrates), which results in increased J_{SC}, increased V_{OC}, and increased FF. The co-firing process also results in a more uniform Al BSF and a decreased BSRV. These above-described variables result in an increased solar cell bulk lifetime and increased solar cell efficiency, which are unexpected and are obtained using the ramp up stage, hold stage, and ramp down stage, as described above.

In Block 214, post belt co-firing treatment can be conducted. Following the co-firing event, the Ag contacts 110 can be covered with photoresist, for example, to enable the edge isolation of the cells with the dicing saw and/or a photolithography process followed by etching in, for example, a buffered oxide etchant (BOE) to remove the shunting path. The most common approach is the isolation of the cells using dicing of each silicon wafers, without the use of photolithography and etching thereafter, followed by a forming gas annealing process at about 350 to 450° C. for a specified time of about 15 to 20 minutes, for example.

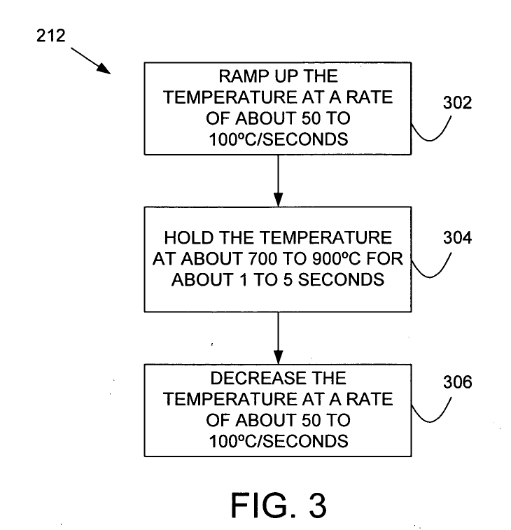

FIG. 3 illustrates a flowchart 212 describing an exemplary method of the rapid co-firing process, which forms the co-fired silicon solar cell structure 100 shown in FIG. 1. For example, the co-firing process occurs in a three-zone lamp-heated belt furnace at specified belt speeds and temperatures to achieve certain ramp up stages, hold stages, and ramp down stages.

In Block 302, the belt furnace temperature can be ramped up at a rate of about, for example, 50 to 100° C./s, about 50 to 80° C./s, and about 50 to 60° C./s, as described above. The rate can be achieved, at least in part, by the belt speed, the temperature of the belt furnace, and dimensions of the belt furnace.

In Block 304 the belt furnace can be held at a temperature of about, for example, 700 to 900° C., about 750 to 850° C., and about 740 to 780° C. for about 1 to 5 seconds, about 1 to 3 seconds, and about 1 to 2 seconds.

In Block 306 the belt furnace temperature can be ramped down at rate of, for example, about 50 to 100° C./s, about 50 to 80° C./s, and about 50 to 60° C./s.

Although not intending to be bound by theory, the co-firing process drives the atomic hydrogen from the SiNₓ layer into the Si underneath on the p-silicon substrate 102 to passivate the defects in it, thus producing an improved bulk minority carrier lifetime. Thus, for example, a 1 second firing of SiNₓ/Al enhances processing throughput, bulk lifetime, and cell efficiency without sacrificing the Al-BSF quality. The improved BSF results from fast ramp up rates, very short hold time at about 740° C., for example, and fast ramp down rates, thus producing improved bulk lifetime by enhancing the retention of hydrogen at defects. This improvement is characterized by an increased lifetime from about 1 μs to 20-125 μs, for example. The co-firing temperature allows for the simultaneous formation of Ag front side contacts and Al back-surface field (p⁺) and Al back contacts with the p-silicon substrate using Ag paste and Al paste, respectively. Further, this process produces a back surface recombination velocity (BSRV) value of about 200 to 900 cm/s and solar cell fill factors (FF) of about 0.75-0.80, due to good ohmic contacts.

Good ohmic contacts can be characterized, in part, by contact resistance (ρ_{C}), series resistance (R_{S}) and junction leakage current density (J_{O2}) values. The positioning of a low frequency Si₃N₄ film at about 400 to 450° C. provides surface passivation that lowers the surface recombination velocity (SRV) from about 250,000 cm/s to about 60,000 cm/s. Thus, resulting in a lower emitter saturation current (Jₒₑ) 400 to 90 pA/cm² and increased open circuit voltage (V_{oc}). For example, a co-firing event using PV168 Ag paste, providing good surface passivation gives about 1% higher cell efficiency with 1.96 mA/cm² higher short circuit current density (J_{sc}).

Current production of screen-printed cells in production are fabricated on about a 30 to 45 Ω/sq. emitter, resulting in poor surface passivation and blue response. The present disclosure describes processes that includes a lightly-doped emitter including greater than about 55 Ω/sq, about 60 Ω/sq, about 65 Ω/sq, about 70 Ω/sq, about 75 Ω/sq, about 80 Ω/sq, about 85 Ω/sq, about 90 Ω/sq, about 95 Ω/sq, and about 100 Ω/sq emitter, with good surface passivation and thus, an enhanced short circuit current density (J_{SC}) due to better blue response.

In one embodiment, an Ag paste (e.g., PV168 Ag paste that can be purchased from DuPont is used. The PV168 Ag paste is constructed such that it etches through the SiN_{X} layer without excessively etching the Si (emitter) underneath under the conditions of the co-firing process described herein. This allows for better contacts with the n⁺-type emitter and thus providing a lower Ag crystallite concentration near the junction. In this regard, having no crystallite shunting the junction, results in higher open circuit voltage (V_{OC}) and higher fill factor (FF), and thus a higher efficiency solar cell. After screen-printing, the organic constituents in the pastes are then burnt-out during a burn-out step at a specified belt speed at about 20 to 30 ipm in the belt-furnace with sample temperature reaching about 350 to 450° C. The treated p-silicon substrate is then co-fired at high belt speeds of about 80 to 120 ipm at about 740° C. to 800° C., which is less than the melting point of Ag.

For the purposes of illustration only, the co-fired silicon solar cell structure 100 is described with particular reference to the below-described fabrication method. The fabrication method is described from the point of view shown in FIG. 1.

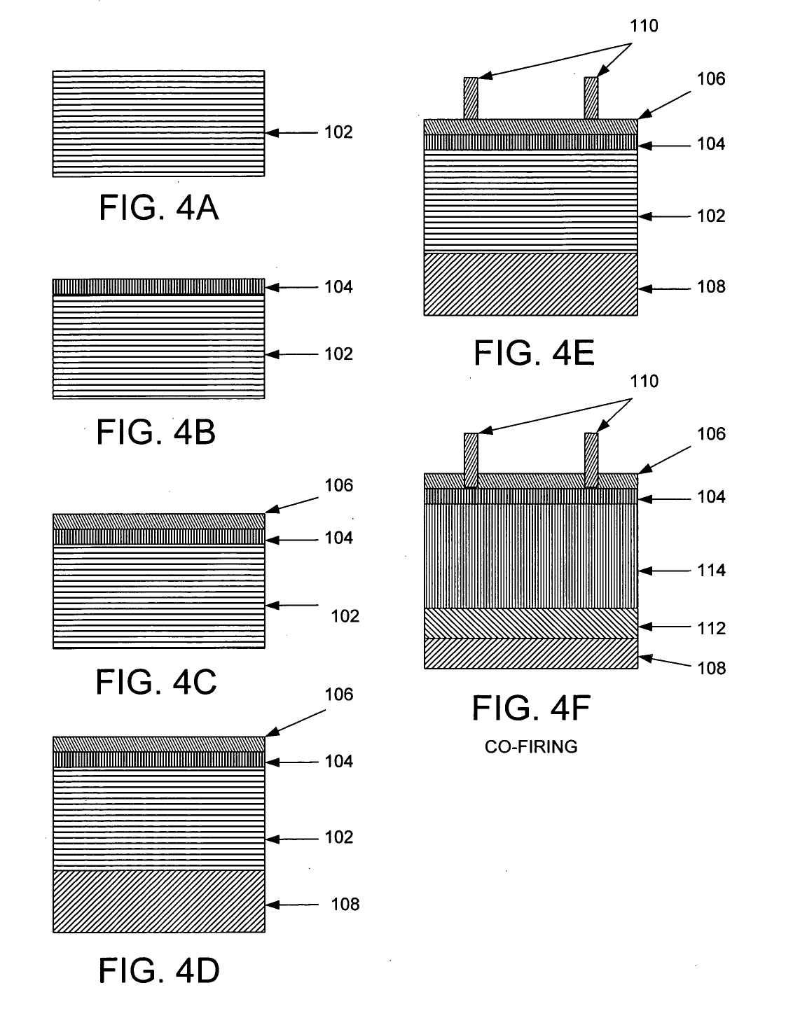

For clarity, some portions of the fabrication process are not included in FIGS. 4A through 4F. The following fabrication process is not intended to be an exhaustive list that includes every step in the fabrication of the co-fired silicon solar cell structure 100. In addition, the fabrication process is flexible and the process steps may be performed in a different order than the order illustrated in FIGS. 4A through 4F.

In general, the silicon solar cell structure 100 can be formed in a manner described in FIGS. 4A through 4F. FIGS. 4A through 4F are schematics that illustrate an exemplary method of forming the silicon solar cell structure 100 shown in FIG. 1. FIG. 4A illustrates the p-silicon substrate 102. FIG. 4B illustrates the formation of the n⁺-type emitter 104 formed on the top-side of the p-silicon substrate 102. The n⁺-type emitter 104 can be formed using techniques such as, but not limited to, the RCA cleaning of the p-silicon substrate 102 followed by POCl₃ diffusion to form the n⁺-type emitter 104.

FIG. 4C illustrates the positioning of a SiNₓ anti-reflective layer 106 on the top-side of the n⁺-type emitter layer 104. The SiNₓ anti-reflective layer 106 can be positioned using techniques such as, but not limited to, a plasma-enhanced chemical vapor deposition (PECVD) process.

FIG. 4D illustrates the positioning of an Al contact 108 on the back-side of the p-silicon substrate 102. The Al contact layer 108 can be positioned using techniques such as, but not limited to, a process in which Al paste is screen-printed on the back-side of the p-silicon substrate 102 and dried at a specified temperature.

FIG. 4E illustrates the positioning of Ag contacts 110 on the top-side of the SiNₓ anti-reflective layer 106. The Ag contacts 110 can be formed using techniques such as, but not limited to, screen-printing. FIG. 4F illustrates the co-fired silicon solar cell structure after rapid co-firing.

Now having described silicon solar cell structure and its methods of fabrication in general, Examples 1 and 8 describe some embodiments of the silicon solar cell structure and uses thereof. While embodiments of the silicon solar cell structure and methods of fabrication are described in connection with Examples 1 and 8 and the corresponding text and figures, there is no intent to limit embodiments of the silicon solar cell structure and its methods of fabrication to these descriptions. On the contrary, the intent is to cover all alternatives, modifications, and equivalents included within the spirit and scope of embodiments of the present disclosure.

It should be noted that ratios, concentrations, amounts, dimensions, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a range of “about 0.1% to about 5%” should be interpreted to include not only the explicitly recited range of about 0.1% to about 5%, but also include individual ranges (e.g., 1%, 2%, 3%, and 4%) and the sub-ranges (e.g., 0.5%, 1.1%, 2.2%, 3.3%, and 4.4%) within the indicated range.

It should be emphasized that the above-described embodiments and the following Examples of the present disclosure are merely possible examples of implementations, and are merely set forth for a clear understanding of the principles of the disclosure. Many variations and modifications may be made to the above-described embodiments. All such modifications and variations are intended to be included herein within the scope of this disclosure and protected by the following claims.

### EXAMPLE 1

Now having described the embodiments of the nanostructure in general, Example 1 describes some embodiments of the nanostructure and uses thereof. The following is a non-limiting illustrative example of an embodiment of the present disclosure that is described in more detail in M. Hilali, J. W. Jeong and A. Rohatgi “A Study of Contact Resistance and Cell Performance of Selective-Emitter Screen-Printed Silicon Solar Cells Using a Self-Doping Paste”, in Proceedings of the 12^{th} Workshop on Crystalline Silicon Solar Cell Materials and Process, Brekenridge, Colorado, pp. 282-285, 2002, which is incorporated herein by reference. This example is not intended to limit the scope of any embodiment of the present disclosure, but rather is intended to provide some experimental conditions and results. Therefore, one skilled in the art would understand that many experimental conditions can be modified, but it is intended that these modifications be within the scope of the embodiments of the present disclosure.

Introduction:

Screen-printed selective-emitter solar cells have been fabricated on FZ Si with efficiencies of about 16.5%. A self-doping paste was used on 100 Ω/sq. emitter to form the selective emitter. A much lower contact resistance was obtained for the self-doping paste PV168 compared to conventional pastes on 100 Ω/sq. Contact resistance for the PV168 self-doping paste on a 100 Ω/sq. was about 1.5 mΩ-cm², which is comparable to that of a conventional paste on a 40 Ω/sq. emitter (about 0.96 mΩ-cm²). The co-fired selective-emitter cell using PV168 showed about 0.1% improvement in absolute efficiency over the 2-step fired conventional cell. Due to the lightly-doped emitter in the selective-emitter cell, the blue response of the IQE was better, contributing to 0.6 mA/cm² improvement in the short-circuit current. The fill factors for both conventional and selective-emitter cells were very close, 0.776 and 0.775 respectively, indicating the effectiveness of the self-doping paste PV168. The selective-emitter cells had an unoptimized silicon nitride passivation. Improved oxide or nitride passivation is expected to increase the performance of the selective-emitter cells even further.

Experimental:

Two types of solar cells (4 cm²) were fabricated on p-type 0.6 Ω-cm 300-μm thick (100) float-zone (FZ) Si wafers: one involving conventional pastes (Table 1) and the other involving the self-doping paste PV168 (Table 2). In Table 1 below, the first cell is a conventional screen-printed cell with a 40-45 Ω/sq. homogeneous emitter using the commercially available paste A, which gave a 16.38% efficient cell. This cell was fabricated using a 2-step firing process: 850° C./2 min. for the Al BSF (back-surface field) and 752° C./40 sec. for the front contact firing. The next two cells in Table 1 had 100 Ω/sq. emitter and the front and back contacts were co-fired using screen-printed pastes A and B under identical conditions (900° C.) to those used for firing the self-doping paste PV168. The cells in Table 2 involve the self-doping paste on emitters of different sheet resistance values (100, 110, 120, 130, and 150 Ω/sq.). All the cells in this set were co-fired (front contact and back Al BSF) at 900° C. at the firing conditions optimized to give good ohmic contact on a 100 Ω/sq. emitter. After cleaning the wafers, the emitters for all the cells were diffused in a POCl₃ tube furnace. After the removal of the phosphorus glass, a SiNₓ single layer antireflection coating (SLARC) was deposited with a refractive index of 1.98 and a thickness of 850 Å. The front-contact grid was screen-printed on top of the SiNₓ, and the front and back metal contacts were either co-fired, or a 2-step firing process was used as explained previously. All screen-printed contacts were fired in a belt-line furnace. In order to assess the quality of the contacts, contact resistance measurements were performed using the transfer length method (TLM) [4] on contact resistance test patterns screen-printed and fired simultaneously with the front-metal grid.

Results and Discussion:

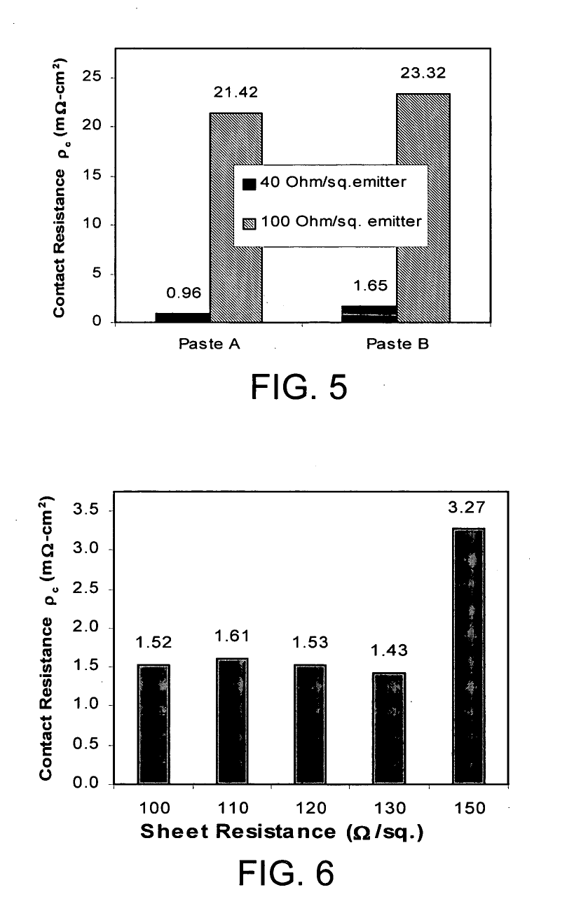

Contact Resistance Analysis: In order to investigate the quality of the front metal contacts, contact resistance measurements were performed. FIG. 5 shows contact resistance measurements for two pastes on 40 and a 100 Ω/sq. emitters. For the 40 Ω/sq. emitter, paste A gave a low contact resistance of 0.96 mΩ-cm² which increased to about 21 mΩ-cm² for the 100 Ω/sq. emitter. Paste B produced even higher contact resistance (1.65 mΩ-cm² on the 40 Ω/sq. emitter and about 23 mΩ-cm² on the 100 Ω/sq. emitter). Paste A gave lower contact resistance values (as low as 2 mΩ-cm² on 100 Ω/sq.) when fired at temperatures slightly higher than the optimized temperature (900° C.) for PV168, suggesting that it also contains some phosphorus. However, high temperature firing of paste A degrades the cell performance resulting in lower open-circuit voltage (V_{oc}) and higher n factor and leakage current.

FIG. 6 shows contact resistance values for the PV168 self-doping paste on emitters of different sheet resistance. The contact resistance is around 1.5 mΩ-cm² for sheet resistance values in the range of 100-130 Ω/sq., and is comparable to that of a conventional paste on a 40 Ω/sq. emitter. The contact resistance for the self-doping paste starts to increase rapidly (3.27 mΩ-cm²) when the sheet resistance increases to 150 Ω/sq.

Cell Data and Analysis: Light and dark I-V measurements were performed to analyze the performance of the cells. As shown in Table 1, the conventional cell with 40 Ω/sq. homogeneous emitter has a fill factor of 0.776 and a reasonably good series resistance of 0.886 Ω-cm² (cell 2-step-40). Cells A-100 and B-100 in Table 1 are fabricated with conventional pastes A and B on 100 Ω/sq. emitter. These cells showed a very high series resistance and low FFs of 0.5-0.6.

TABLE 1
Cells fabricated using front metal pastes A and B.

| Cell | V_{oc} | J_{sc} | | Eff | | Rₛ | Rₛₕ |
|---|---|---|---|---|---|---|---|
| Name | (mV) | (mA/cm²) | FF | (%) | n factor | (Ω-cm²) | (Ω-cm²) |
| 2-step-40 | 635.3 | 33.20 | 0.776 | 16.38 | 1.11 | 0.886 | 1,507 |
| A-100 | 619.5 | 33.00 | 0.594 | 12.14 | 1.07 | 4.812 | 18,297 |
| B-100 | 571.6 | 32.89 | 0.536 | 10.08 | 2.62 | 3.208 | 15,078 |

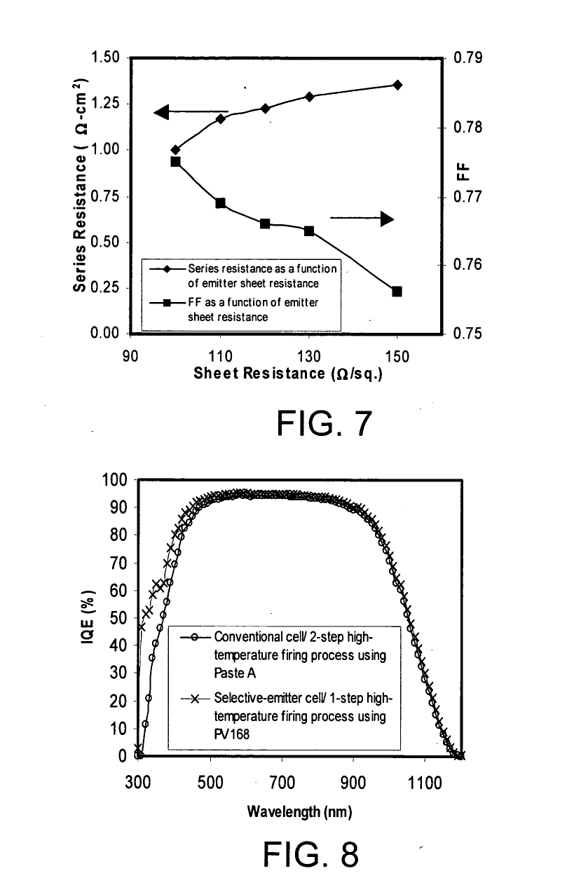

Selective-emitter cells in Table 2 and FIG. 7 show that the series resistance increases with the increase in emitter sheet resistance. However, for the 100-130 Ω/sq. emitters, the series resistance is only dictated by the higher emitter sheet resistance and not by the contact resistance as shown by FIG. 6. The FF also decreases slightly and systematically as the emitter sheet resistance increases. Thus, the performance of these selective-emitter cells (Table 2) could be improved significantly by the optimized front metal contact grid design using finer gridlines in conjunction with smaller grid spacing. The front metal grid used in this study was optimized for the 40 Ω/sq. emitter.

TABLE 2
Front metal contact self-doping paste PV168 on
emitters of different sheet resistance.

| Cell Name | V_{oc} (mV) | J_{sc} (mA/cm²) | FF | Eff (%) | n factor | Rₛ (Ω-cm²) | Rₛₕ (Ω-cm²) |
|---|---|---|---|---|---|---|---|
| PV168-100 | 627.1 | 33.90 | 0.775 | 16.47 | 1.01 | 1.003 | 3,353 |
| PV168-110 | 622.0 | 33.40 | 0.769 | 15.95 | 1.01 | 1.171 | 8,222 |
| PV168-120 | 626.5 | 33.60 | 0.766 | 16.13 | 1.01 | 1.225 | 9,681 |
| PV168-130 | 625.4 | 33.30 | 0.765 | 15.93 | 0.99 | 1.293 | 88,757 |
| PV168-150 | 617.90 | 33.50 | 0.7562 | 15.67 | 1.00 | 1.357 | 13,111 |

FIG. 8 shows the IQE plot for the conventional cell with 40 Ω/sq. homogeneous emitter and a selective-emitter cell with a 100 Ω/sq. emitter. The short-wavelength response of the co-fired selective-emitter cell is superior to that of the 2-step fired conventional cell, resulting in 0.6 mA/cm² improvement in the current. The long-wavelength response of both cells is almost identical, indicating the same BSF quality. The short-wavelength response can be improved further by better surface passivation because the SiNₓ SLARC used in this study was not optimized for lowest surface recombination velocity.

Conclusion:

Contact resistance measurements show that the PV168 Ag paste can achieve reasonably low contact resistance on ≧100 Ω/sq. emitter with the appropriate firing conditions. Contact resistance values are comparable (<2 mΩ-cm²) to those of conventional Ag pastes on a 40 Ω/sq. emitter. Screen-printed selective-emitter cells with an efficiency of about 16.5% were achieved on FZ silicon with 0.6 mA/cm² enhancement in J_{SC} over the conventional 40 Ω/sq. cells. Fill factors were about 0.775 for both selective-emitter and conventional cells. Improved surface passivation and optimized grid design can increase the efficiency of selective-emitter cells significantly over other cells.

### REFERENCES

[1] M. Hilali, J.-W. Jeong, A. Rohatgi, D. L. Meier, and A. F. Carroll, “Optimization of self-doping Ag paste firing to achieve high fill factors on screen-printed silicon solar cells with a 100 Ω/sq. emitter,” Proc. of the 29th IEEE PVSC, May 2002, in press.
[2] D. L. Meier, H. P. Davis, R. A. Garcia, J. A. Jessup, and A. F. Carroll, “Self-doping contacts to silicon using silver coated with a dopant source,” Proc. of the 28^{th} IEEE PVSC, 2000, pp. 69-74.
[3] D. L. Meier, H. P. Davis, R. A. Garcia, J. A. Jessup, P. Hacke, S. Yamanaka, and J. Salami, “Self-doping silver contacts for silicon solar cells,” Proc. 11^{th} Workshop on Crystalline Silicon Solar Cell Materials and Processing, Aug. 19-22, 2001, pp. 129-136.
[4] Deiter K. Schroder, Semiconductor Material and Device Characterization, John Wiley & Sons, Inc., 1990, pp. 119-120.

### EXAMPLE 2

Now having described the embodiments of the nanostructure in general, Example 2 describes some embodiments of the nanostructure and uses thereof. The following is a non-limiting illustrative example of an embodiment of the present disclosure that is described in more detail in M. Hilali, A. Rohatgi, S. Asher, “Development of screen-printed silicon solar cells with high fill factors on 100 Ω/sq emtters,” IEEE Trans. Electron. Dev., 51, pp. 948-955 (2004), which is incorporated herein by reference. This example is not intended to limit the scope of any embodiment of the present disclosure, but rather is intended to provide an exemplary set of specific experimental conditions and results. Therefore, one skilled in the art would understand that many experimental conditions can be modified, but it is intended that these modifications be within the scope of the embodiments of the present disclosure.

Introduction:

High-quality screen-printed Ag contacts were achieved on high-sheet resistance emitters (100 Ω/sq.) by rapid alloying of PV168 Ag paste. Excellent specific contact resistance (about 1 mΩ-cm²) in conjunction with high fill factor (0.775) were obtained on 100 Ω/sq. emitters by a 900° C. spike firing of PV168 paste in a belt furnace. The combination of the alloying characteristics of the PV168 Ag paste and optimized single-step rapid low-thermal budget firing resulted in a cost-effective manufacturable process for high-efficiency Si solar cells. In addition, the co-fired 100 Ω/sq. cell showed a slight improvement over the 2-step fired conventional 45 Ω/sq.-emitter cell. Light-doping in the 100 Ω/sq.-emitter cell resulted in better blue response compared to the conventional cell, contributing to 0.7 mA/cm² improvement in the short-circuit current density.

Experimental:

Screen-printed n⁺-p-p⁺ solar cells (4 cm²) were fabricated on single crystal Si using different Ag pastes and firing conditions on 45 and 100 Ω/sq. emitters. P-type, 0.6 Ω-cm, 300-μm thick (100) float-zone (FZ) substrates were used for all the experiments. Silicon wafers were first RCA cleaned followed by POCl₃ diffusion to form the n⁺-emitter. After the phosphorus-glass removal and another, clean PECVD Si₃N₄ antireflection coating (850 Å with an index of 1.98) was deposited on the emitter. Next, an Al paste was screen-printed on the backside and dried at 200° C. The Ag grid was then screen-printed on top of the Si₃N₄ film and Ag and Al contacts were co-fired (single firing step) in a lamp-heated 3-zone belt-line furnace. The cells were then isolated using a dicing saw and annealed in forming gas at 400° C. for about 15 min. In addition to the PV168 Ag paste from DuPont, two other commercially available Ag pastes (A and B) were investigated for comparison. Conventional cells with 45 Ω/sq. emitter were also fabricated using a two-step firing process involving Al firing at a set temperature of 850° C. for 2 min. followed by Ag grid firing in a commercial belt-furnace. In order to understand and compare the quality of contacts for different pastes on the low and high-sheet resistance emitters, I-V, IQE, and Suns-V_{oc} measurements [8] were performed to extract cell parameters and compare short- and long-wavelength response. In addition, SIMS measurements were performed on selected samples to determine the Ag and P doping profiles in the silicon directly underneath the Ag grid using a CAMECA IMS-300 ion microscope. The primary ion beam covered an area of 150 μm×150 μm with a 60-μm aperture, which is restricted to a 20 μm diameter SIMS analysis circular area due to the immersion lens system. The samples were bombarded with 5.5 KeV oxygen primary ions for detecting Ag while 14.5 KeV cesium primary ions were used for detecting P. Finally, the contact resistance measurements were performed using the TLM patterns [9], which were printed during the cell fabrication.

Results and Discussion:

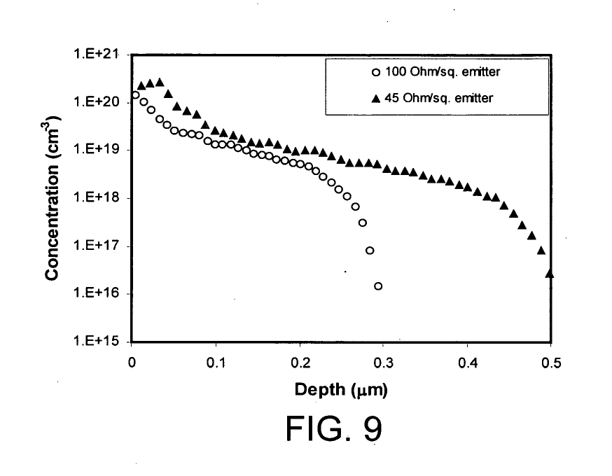

Determination of the 45 and 100 Ω/sq. Emitter Doping Profiles: FIG. 9 shows the spreading resistance measurements for the phosphorus doping profiles for the 100 and 45 Ω/sq. emitters formed in this study. The 100 Ω/sq. emitter had a surface concentration of about 1.5×10²⁰ cm³ with a junction depth of 0.277 μm while the 45 Ω/sq. emitter showed a surface concentration of about 2.27×10²⁰ cm³ with a junction depth of 0.495 μm. The shallow 100 Ω/sq. emitter should lead to higher current due to the thinner dead layer, compared to the 45 Ω/sq. emitter. On the other hand, shallow emitters are more prone to junction shunting due to impurity incorporation from the paste into junction, resulting in lower open-circuit voltage (V_{oc}) and fill factor (FF). If the frit in the paste etches Si excessively, then the Ag metal will reach near the junction and enhance junction leakage current. It is known from the literature that a surface dopant concentration of >10¹⁹ cm⁻³ can be used [10, 11] for a good evaporated, and full area, ohmic contact to n-type Si region, which can lead to the desired contact resistance of <2 mΩ-cm² for silicon solar cells [11]. This assumes full area metal-Si contact, which may not be true for screen-printed contacts due to the presence of a quasi-continuous glass frit layer [12]. This may raise the requirements for surface doping. FIG. 9 shows that both 45 Ω/sq. and 100 Ω/sq. emitters used in this study have surface concentration greater than 1×10²⁰ cm⁻³, which should be sufficient for a good full area ohmic contact. However, in the case of screen-printed contacts, the challenge is to ensure that Ag from the paste can make good contact to the 100 Ω/sq. emitter at an appropriate firing temperature without penetrating too deep into the emitter. Therefore, optimum contact firing conditions were established first for different pastes.

A Study of Conventional Ag Pastes and Firing Conditions on the Performance of Si cells with Low- and High-Sheet-Resistance Emitters: Before investigating the special PV168 paste from DuPont, two commercial Ag pastes were studied. Currently no cell manufacturer uses high-sheet-resistance emitters (≧60 Ω/sq.) because it is difficult to achieve good screen-printed ohmic contact on them using conventional Ag pastes. This is demonstrated in Table 3, where a commercial Ag paste B gave a high FF of 0.785 on a 45 Ω/sq. emitter but the FF value decreased to 0.48 on 100 Ω/sq. emitter for the identical co-firing condition of 850° C. and 80 ipm belt speed. Similarly, optimum firing conditions for a second commercial paste A on the 45 Ω/sq. emitter were found to be 435/585/750° C. for the three zones in conjunction with 15 ipm belt speed. Table 3 shows that using these conditions, paste A gave better results than paste B on the 100 Ω/sq. emitter but the FF (0.70) and V_{oc} (612 mV) were again much lower compared to the 45 Ω/sq emitter cell (FF=0.79, V_{oc}=622 mV).

TABLE 3
I-V DATA FOR CELLS FABRICATED WITH COMMERCIAL PASTES A AND
B USING CO-FIRING PROCESS ON LOW- (40 Ω/SQ. EMITTERS) AND
HIGH-SHEET-RESISTANCE (100 Ω/SQ.) EMITTER CELLS

| | Co-firing | Emitter | V_{oc} | J_{sc} | | Eff | n | Rₛ (Ω- | Rₛₕ (Ω- |
|---|---|---|---|---|---|---|---|---|---|
| Paste | Process | (Ω/sq.) | (mV) | (mA/cm²) | FF | (%) | factor | cm²) | cm²) |
| A | 435/585/750° C./ | 45 | 622.0 | 31.80 | 0.792 | 15.66 | 1.04 | 0.61 | 22,541 |
| | 15 ipm | | | | | | | | |
| A | 435/585/750° C./ | 100 | 612.0 | 32.10 | 0.704 | 13.85 | 1.09 | 2.41 | 1,707 |
| | 15 ipm | | | | | | | | |
| B | 850° C./80 ipm | 45 | 626.5 | 32.60 | 0.785 | 16.02 | 1.09 | 0.64 | 188,040 |
| B | 850° C./80 ipm | 100 | 291.5 | 32.70 | 0.479 | 4.56 | 2.02 | 1.11 | 3,071 |

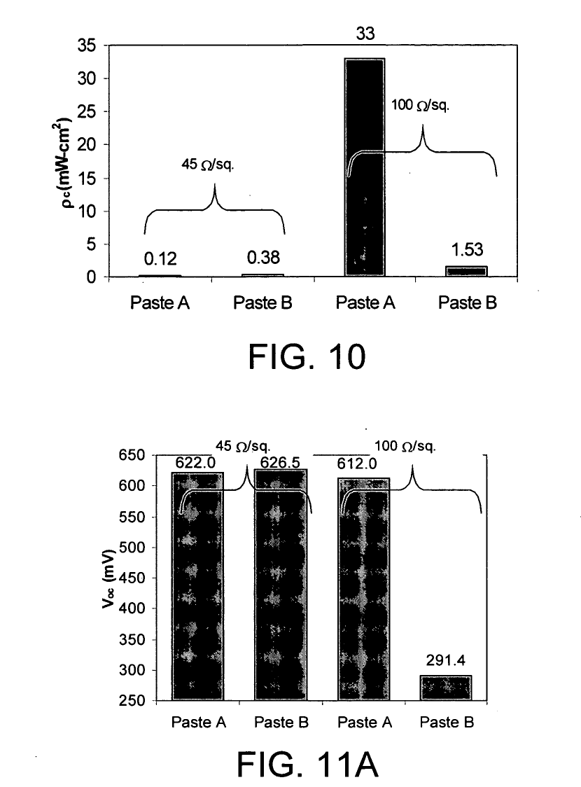

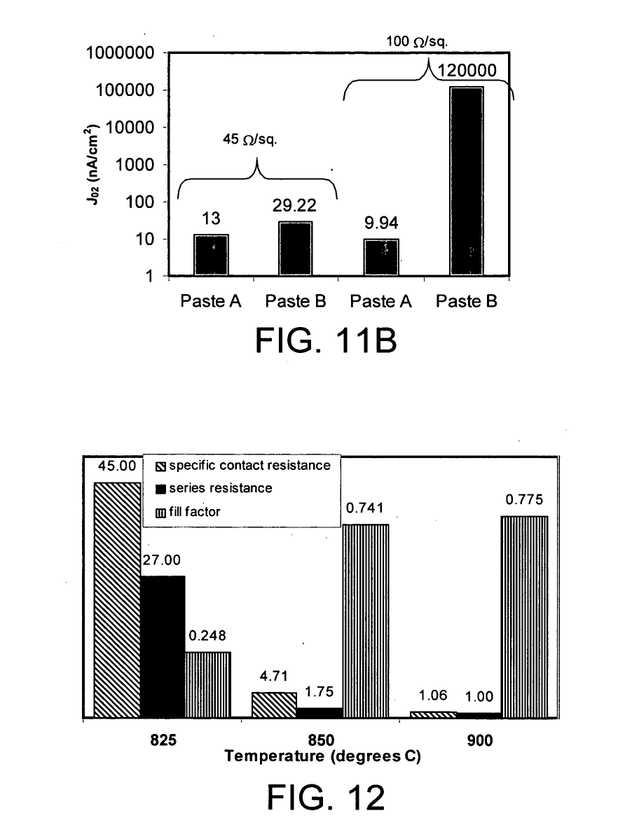

In order to understand the significant difference in efficiency and FF for the two sheet resistances, specific contact resistance (ρ_{c}) measurements were performed by the TLM method. Specific contact resistance should be below 2 mΩ-cm². FIG. 10 shows that in the case of the 45 Ω/sq. emitter, both pastes A and B gave good ohmic contacts with very low ρ_{c} values of 0.12 and 0.38 mΩ-cm², respectively. However, for the 100 Ω/sq. emitter, paste A gave very high ρ_{c} value of 33 and paste B an acceptable value of 1.53 mΩ-cm². FIG. 11A shows that both pastes showed a decrease in V_{oc} for the 100 Ω/sq. emitter with paste B resulting in a much more significant loss in V_{oc}. This is explained by the junction leakage current or J₀₂ measurements in FIG. 11B which revealed that paste B introduces much higher junction leakage current on the 100 Ω/sq. (J₀₂=120,000 nA/cm²) emitter. Paste A gave low J₀₂ values of 13 and about 10 nA/cm², which should not degrade FF, for the 45 and 100 Ω/sq. emitters, respectively. Thus, both commercial pastes A and B failed on the 100 Ω/sq. emitter, paste A due to very high contact resistance and paste B due to very high J₀₂.

Optimization of PV168 Ag Paste Firing to Achieve Good Contacts on 100 Ω/sq. Emitter: Paste composition and firing cycle can significantly influence series resistance, junction leakage, and FF. The previous section showed that commercial pastes A and B failed on 100 Ω/sq. emitter. The following sections describe how the impact of set temperature and belt speed lead to the firing conditions that can produce good contacts to 100 Ω/sq. emitter using the PV168 Ag paste.

Effect of Firing Temperature on the Performance of Cells made with PV168 Ag Paste: First the effect of firing temperature on the FF of the cells is examined using high belt speed (≧80 ipm), referred to as “spike firing” in this example. FIG. 12 shows that spike firing of the PV168 Ag paste at a set temperature below the Ag—Si eutectic temperature of 835° C. gave the lowest FF (0.25) in conjunction with the highest series resistance (27 Ω-cm²). The FF improved to 0.741 at 850° C. and at a set temperature of 900° C., which is well above the Ag—Si eutectic temperature, very good FF of 0.775 was achieved. It is important to realize that the actual sample temperature is generally lower than the set temperature, especially for faster belt speeds. Sample profiling showed that the sample temperature reached about 835° C. for a short time (few seconds) for the 900° C./80 ipm condition. The sample temperature was well below the Ag—Si eutectic at set temperatures of 850° C. or less with 80 ipm belt speed. FIG. 12 also shows that the series resistance of the cell decreased from 27 Ω-cm² to 1 Ω-cm² when the firing set temperature was increased from 825° C. to 900° C. in the belt-furnace. This is also reflected in the reduction of contact resistance from a very high value of 45-mΩ-cm² down to 1.06-mΩ-cm², where it should have little effect on the FF. Thus, unlike the conventional pastes, when the PV168 paste is fired at a set temperature of about 900° C. to trigger Ag—Si alloying reaction, it produces a good ohmic contact on 100 Ω/sq. emitter, with R_{S} about 1 Ω-cm², ρ_{c} of about 1 mΩ-cm², J₀₂=9.75 nA/cm², and FF of about 0.775.

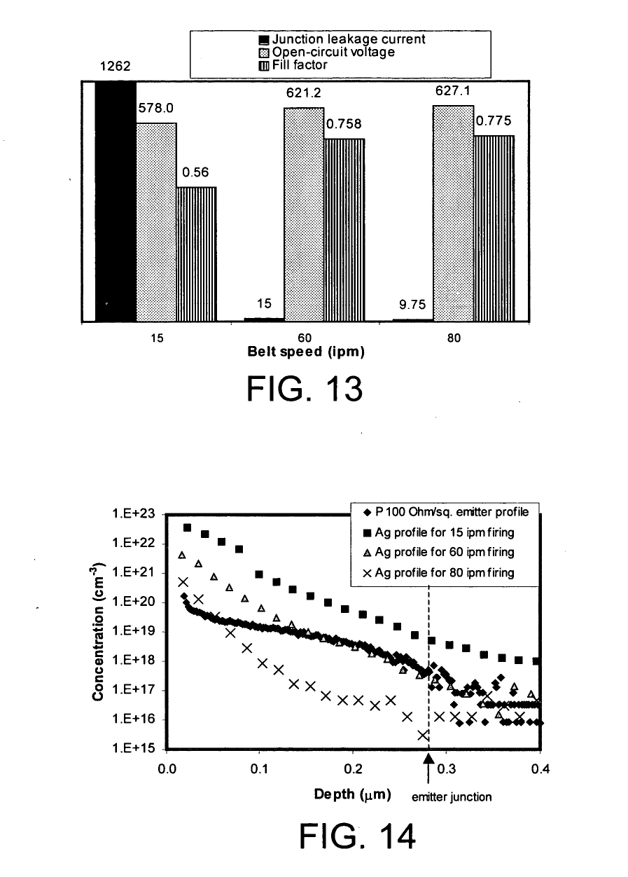

Effect of Belt Speed on the Performance of Cells made with PV168 Ag Paste: Since the combination of set temperature and belt speed dictate the thermal budget of the sample, the role of belt speed on the contact formation was also examined. FIG. 13 summarizes the effect of belt speed on V_{oc} and J₀₂. Slow firing (15 ipm) at 910° C. resulted in very high J₀₂ of 1262 nA/cm² with a corresponding FF of 0.56. It is important to note that slow firing in the belt-furnace (longer firing time) raises the actual sample temperature for the same set temperature. For the 900° C. set temperature, faster belt firing speeds of 60 and 80 ipm gave much lower J₀₂ values of 15 and 9.75 nA/cm², respectively, which correspond very well with the higher FF and V_{oc} (FIG. 13). The firing condition of 80 ipm at 900° C. gave the best cell performance and a good FF of 0.775.

SIMS Analysis of PV168 Ag Contact to 100 Ω/sq. Emitter: SIMS measurements were performed on Si underneath the Ag contacts to gain a better understanding of the success of PV168 screen-printed contacts on 100 Ω/sq. emitters. Ag metal was etched off prior to the SIMS measurements. SIMS data in FIG. 14 show that slow belt-speed firing at 910° C. set temperature gives much higher concentration of Ag in the Si, while fast firing results in much lower amount of Ag at or near the emitter/base junction. Recall that spreading resistance gave a junction depth of 0.277 μm for the 100 Ω/sq. emitter (FIG. 9). Ag concentrations at the n⁺-p junction (0.277 μm) were found to be 6×10¹⁸ cm⁻³, 2×10¹⁷ cm⁻³ and 2×10¹⁶ cm⁻³ for the belt speeds of 15, 60, and 80 ipm, respectively.

It is clear from FIGS. 13 and 14 that the faster firing leads to lower Ag concentration near the junction edge, which in turn reduces junction leakage current and gives higher V_{oc}. This is consistent with the work of Van Craen et al. [13], who showed that the solar cell efficiency decreases with the increase in Ag concentration near the junction.

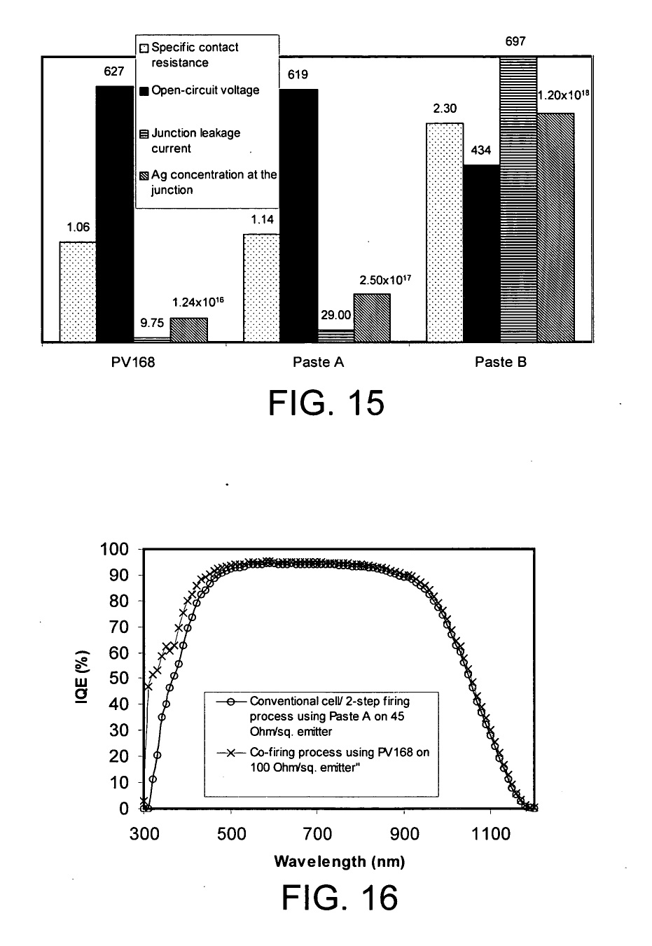

Comparison of PV168 Ag Paste with the Other Commercial Ag Pastes at Firing Temperatures Around the Ag—Si Eutectic: The last section demonstrated that the PV168 Ag paste is capable of producing high FFs and cell efficiencies on 100 Ω/sq. emitters, provided spike firing is performed at a set temperature above the Ag—Si eutectic temperature, resulting in sample temperature of about 835° C. for a very short time. PV168 is made by DuPont using a proprietary technology involving a somewhat different Ag particle morphology, content, and frit composition. In order to support that the PV168 is different and superior to conventional pastes for making good contacts to 100 Ω/sq. emitter, two commercial Ag pastes A and B, along with the PV168, were used to fabricate cells on the 100 Ω/sq. emitter using identical firing condition (900° C./80 ipm spike co-firing). Recall that this condition leads to an actual sample temperature of about 835° C. Cell data is shown in Table 4 along with a 45 Ω/sq. emitter cell made with conventional paste A. FIG. 15 shows that the V_{oc} decreases while J₀₂ increases monotonically for cells made from pastes PV168, A and B, respectively. The lowest J₀₂ value for the PV168 paste suggests much lower junction leakage as compared to the other two pastes. It is even lower than the J₀₂ for the cell with paste A on conventional 45 Ω/sq.-emitter, which has a deep junction. This indicates that the PV168 Ag paste works via a different mechanism than the two conventional pastes. SIMS analysis was performed again to understand this hypothesis by determining the Ag penetration into the emitter. The Ag concentrations at the junction (FIG. 15) were found to be 1.24×10¹⁶ cm⁻³, 2.50×10¹⁶ cm⁻³, and 1.20×10¹⁶ cm⁻³ for pastes PV168, A, and B, respectively. Again, the V_{oc} was found to correlate very well with the Ag concentration at the junction: the higher the Ag concentration near the junction edge, the lower the V_{oc}.

TABLE 4
I-V DATA FOR A 2-STEP FIRED CONVENTIONAL CELL WITH 40 Ω/SQ. EMITTER
AND FOR CO-FIRED CELLS ON HIGH-SHEET-RESISTANCE (100 Ω/SQ.)
EMITTERS USING SILVER PASTES A, B, AND PV168

| | Firing | Emitter | V_{oc} | J_{sc} | | Eff | n | Rₛ (Ω- | Rₛₕ (Ω- |
|---|---|---|---|---|---|---|---|---|---|
| Paste | Process | (Ω/sq.) | (mV) | (mA/cm²) | FF | (%) | factor | cm²) | cm²) |
| A | 2-step firing | 45 | 635.30 | 33.20 | 0.776 | 16.38 | 1.11 | 0.89 | 1,507 |
| A | 900° C./80 ipm | 100 | 619.50 | 33.20 | 0.761 | 15.65 | 1.10 | 1.05 | 5,092 |
| | co-fring | | | | | | | | |
| B | 900° C./80 ipm | 100 | 571.60 | 32.89 | 0.536 | 10.08 | 2.62 | 3.21 | 15,078 |
| | co-firing | | | | | | | | |
| PV168 | 900° C./80 ipm | 100 | 627.10 | 33.90 | 0.775 | 16.47 | 1.01 | 1.00 | 3,353 |
| | co-firing | | | | | | | | |

In order to improve the basic understanding further, specific contact resistance measurements were performed. FIG. 15 also shows that the specific contact resistance for all the 3 pastes was less than 3 mΩ-cm² on 100 Ω/sq. emitter, which is quite acceptable for screen-printed contacts and should not appreciably degrade the FF. For the 100 Ω/sq.-emitter cells, PV168 gave the lowest specific contact resistance (1.06 mΩ-cm²) followed by Paste A (1.14 mΩ-cm²), and Paste B (2.3 mΩ-cm²). These results indicate that the problem with conventional pastes A and B is not with the contact resistance to 100 Ω/sq. emitter when using the disclosed firing condition. It has also been observed [14, 15] that hydrogen annealing of over-fired solar cells improves the contact resistance, which is in agreement with the results in FIG. 15, since all the cells are exposed to hydrogen treatment for about 15 min. after firing. Instead, when higher temperatures (i.e., set temp. ≈900° C.) to achieve reasonable contact resistance are gone to, the Ag penetration into the junction becomes excessive, which increases the J₀₂ and lowers the V_{oc} (FIG. 15). On the other hand, Table 3 and FIGS. 10, 11A and 11B reveal that if lower temperatures (set temp. ≦850° C.) to prevent excessive Ag penetration are maintained, the contact resistance becomes high and degrades the FF and cell performance. Paste composition of PV168 is such that at or around the eutectic temperature with spike firing probably a shallow eutectic region is formed, allowing large number of Ag particles to contact the Si emitter. The frit content and composition is such that it etches through the Si₃N₄ without excessively etching the Si emitter underneath. The Ag penetration into Si for the PV168 may be retarded due to the frit content and composition and the Ag particle morphology and surface energy. Contact formation mechanisms [16, 17] for widely used commercial pastes generally involves fluidization of the glass flit upon heating, wetting the surface, and then etching the antireflection coating and Si emitter. Therefore, a higher firing temperature results in deeper etching of Si and higher Ag penetration. It appears that in the case of PV168, etching of Si by the frit is minimal and the contact formation takes place via a very thin eutectic region or Ag—Si alloy. The frit in PV168 seems to dissolve the Ag first during the heating rather than the Si. The molten Ag/frit combination then etches the Si₃N₄ antireflection coating to reach the emitter and form shallow eutectic alloy. This explains why it is important to reach the Ag—Si eutectic temperature of 835° C. [18] during the fast contact firing cycle.

Internal Quantum Efficiency (IQE) Analysis to Support the Benefit of the Lightly-Doped Screen-Printed Emitter Cell Fabricated by a Manufacturable Spike Co-Firing Process: FIG. 16 shows the IQE plots of a conventional 45 Ω/sq. cell fabricated with 2-step firing using silver paste A and the 100 Ω/sq. emitter cell co-fired using PV168 paste. It is clear from the figure that the short-wavelength response of the co-fired 100 Ω/sq. cell is superior to that of the conventional cell. This is because 0.277 μm deep lightly-doped emitter reduces the dead layer thickness, Auger recombination, and the heavy doping effects. This resulted in the observed 0.7 mA improvement (Table 4) in JSc of the 100 Ω/sq. cell over the 0.5 μm deep 45 Ω/sq.-emitter cell. It is also interesting to note that the long-wavelength response of both the cells is almost identical, indicating comparable back-surface field (BSF). The BSRV was estimated to be at 600 cm/s but matching the experimental long-wavelength IQE with the calculated IQE using PC1D model [19]. One purpose of two-step firing in the 45 Ω/sq. cell in FIG. 16 was to first achieve a good BSF at 850° C., and then fire the Ag contacts at lower temperature. However, co-firing with PV168 Ag paste on the front at 900° C. set temperature with high belt speed of 80 ipm is able to accomplish both: an effective BSF and a good ohmic contact on the front. This reduces the number of process steps and processing time, without compromising the cell performance. In addition, it allows the formation of screen-printed contacts on 100 Ω/sq. emitter without any additional cost.

Significant Enhancement in the Performance of 100 Ω/sq.-Emitter Cell with High-Quality Front-Surface Passivation: In the previous sections, it was demonstrated that screen-printed cells on 100 Ω/sq. emitter can be achieve with good ohmic contact, fill factor, and 0.7 mA/cm² higher J_{SC}. However, the efficiency improvement over the conventional 45 Ω/sq. emitter was about 0.1% absolute. This was due to somewhat lower V_{oc} of the 100 Ω/sq.-emitter cell because of the lower quality surface passivation. In order to enhance the understanding of this aspect and increase the efficiency gap between the 100 and 45 Ω/sq.-emitter cells, additional device modeling and IQE analyses were performed to quantify the front-surface recombination velocity. In addition, 100 Ω/sq. emitter cells were fabricated with low-frequency deposition of Si₃N₄ film which gives superior passivation to the high-frequency Si₃N₄ film deposited by our process schemes.

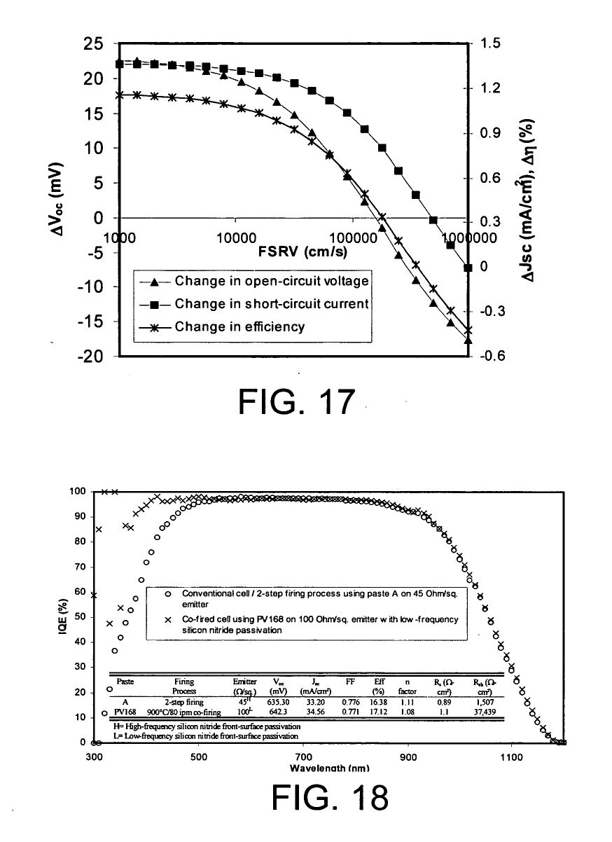

Matching the measured and calculated short-wavelength IQE gave an effective FSRV of 60,000 cm/s for the low-frequency Si₃N₄ passivated 100 Ω/sq. emitter. Similarly, IQE matching gave an effective FSRV of 250,000 cm/s and 200,000 cm/s for high-frequency Si₃N₄ passivated 100 Ω/sq. emitter and 45 Ω/sq. emitter cells, respectively. Furthermore, model calculations in FIG. 17 show that if the front-surface passivation quality is bad (105 cm/s) for the high-sheet resistance emitter (100 Ω/sq.) cell the V_{oc} and efficiency could actually would be lower than that of a 45 Ω/sq.-emitter cell. Model calculations in FIG. 17, show that compared to the 45 Ω/sq.-emitter cell, the V_{oc} of a 100 Ω/sq.-emitter cell starts to decrease at an FSRV >155,000 cm/s while the loss in efficiency starts to degrade at a somewhat higher FSRV of 355,000 cm/s because the short-circuit current (J_{SC}) remains higher for the 100 Ω/sq. emitter cells until the FSRV value exceeds 10⁶ cm/s. FIG. 17 also shows that for an FSRV of 250,000 cm/s, the expected loss in V_{oc} compared to the 45 Ω/sq. should be 5.3 mV. This agrees well with our experimental observations shown in Table 4 for the high frequency nitride cells where the conventional 45 Ω/sq.-emitter cell had a V_{oc} of 635.3 mV and the 100 Ω/sq.-emitter cell showed a V_{oc} of 627.1 mV. FIG. 18 shows the comparison of a 100 Ω/sq.-emitter cell with low-frequency Si₃N₄ passivation (FSRV=60,000 cm/s) and conventional 45 Ω/sq.-emitter cell with high-frequency Si₃N₄ passivation (FSRV=250,000 cm/s). In accordance with model calculations, the 100 Ω/sq.-emitter cell with the superior low-frequency Si₃N₄ passivation, gave a V_{oc} of 642.3 mV which is 7 mV higher than the V_{oc} of the 45 Ω/sq.-emitter cell. This also agrees with the model calculations, which predicted an increase of about 9 mV due to the improved surface passivation. The current was again much higher, FIG. 18, 34.56 mA/cm² for the well-passivated (low-frequency nitride) 100 Ω/sq.-emitter cell as opposed to 33.9 mA/cm² (high-frequency nitride) and 33.2 mA/cm² for the 45 Ω/sq.-emitter cell with high-frequency Si₃N₄ passivation. This resulted in a significant increase in overall efficiency of 100 Ω/sq.-emitter cell compared to the 45 Ω/sq.-emitter cell. The difference in efficiency was now about 0.75% with absolute efficiency reaching 17.12%. The surface recombination effects due to the metal contacts are folded into the effective recombination velocity extracted from model calculations and the IQE analysis. This could account for slight differences in V_{oc} between the measured data and model calculations.

Conclusion:

Screen-printed solar cells are generally made on 30-60 Ω/sq., due to problems with contacts on high-sheet-resistance emitters. This results in appreciable loss in performance due to heavy-doping effects and high FSRV. This example demonstrates that it is possible to obtain high fill factors on 100 Ω/sq. emitters with a manufacturable single-printing and firing scheme using PV168 Ag paste from DuPont. In this study, fundamental understanding and process optimization involving rapid firing at or above the Ag—Si eutectic temperature resulted in high fill factors of ≧0.775. Two other commercial pastes gave poor contacts on 100 Ω/sq. emitter, when fired using the same conditions, due to excessive Ag penetration near the junction. This is attributed to excessive Si etching by the frit in the pastes at or above the eutectic temperature. Below the eutectic temperature when there is no excessive Ag penetration, high contact resistance becomes the problem. The IQE analysis of a conventional cell on a 45 Ω/sq emitter and our 100 Ω/sq.-emitter cell showed an appreciable improvement in the blue response due to the lightly doped emitter. The rapid co-firing process developed for the PV168 also gave good BSF at no additional cost. Finally it has been shown that an efficiency enhancement of about 0.75% is achievable if the front-surface passivation is improved in the high-sheet resistance 100 l/sq. emitter, resulting in efficiencies in excess of 17%.

### REFERENCES

[1] Johan F. Nijs, Jozef Sclufcik, Jozef Poortmans, S. Sivoththaman, and Robert P. Mertens, “Advanced Manufacturing Concepts for Crystalline Silicon Solar Cells”, IEEE Transactions on Electron Devices, vol. 46, no. 10, October 1999, pp. 1948-1969.
[2] A. Rohatgi, M. Hilali, D. L. Meier, A. Ebong, C. Honsberg, A. F. Carroll, and P. Hacke, “Self-aligned self-doping selective emitter for screen-printed silicon solar cells,” Proc. of the 17^{th} European Solar Energy Conference, Munich, Germany, October 2001, pp. 1307-1310.
[3] J. Horzel, J. Szlufcik, J. Nijs, and R. Mertens, “A Simple Processing Sequence for Selective Emitters,” Proceedings of the 26^{th} Photovoltaic Specialists Conference, Anaheim, Calif., September 1997, p. 139-142.
[4] D. S. Ruby, P. Yang, M. Roy ad S. Narayanan, “Recent Progress on the Self-Aligned, Selective-Emitter Silicon Solar Cell,” Proceedings of the 26^{th} Photovoltaic Specialists Conference, Anaheim, Calif., September 1997, p. 39-42.
[5] D. L. Meier, H. P. Davis, R. A. Garcia, J. A. Jessup, and A. F. Carroll, “Self-doping contacts to silicon using silver coated with a dopant source,” Proc. of the 28^{th} IEEE PVSC, 2000, pp. 69-74.
[6] D. L. Meier, H. P. Davis, P. Hacke, R. A. Garcia, S. Yamanaka, J. Salami, and J. Jessup, “Self-doing, screen-printed silver contacts applied to IBC and PhosTop Dendritic Web Silicon Solar Cells,” Proc. of the 17^{th} European Solar Energy Conference, Munich, Germany, October 2001, pp. 1323-1326.
[7] L. M. Porter, A. Teicher, and D. L. Meier, “Phosphorus-doped, silver-based pastes for self-doping ohmic contacts for crystalline silicon solar cells,” Solar Energy Materials and Solar Cells, vol. 73, 2002, pp. 209-219.
[8] R. A. Sinton, A. Cuevas, “A quasi-steady open-circuit voltage method for solar cell characterization,” Proc. of the 16^{th} European Solar Energy Conference, Vol. II, Glasgow, United Kingdom, 2000, pp. 1152-1155.
[9] Deiter K. Schroder, Semiconductor Material and Device Characterization, John Wiley & Sons, Inc., 1990, pp. 119-120.
[10] A. Y. C. YU, “Electron Tunneling and Contact Resistance of Metal-Silicon Contact Barriers,” Solid-State Electronics, 1970, Vol. 13, pp. 239-247.
[11] Deiter K. Schroder and Daniel L. Meier, “Solar Cell Contact Resistance-A Review,” IEEE Transactions on Electron Devices, Vol. ED-31, No. 5, May 1984, pp. 637-647.
[12] C. Ballif, D. M. Huljic, G. Willeke, and A. Hessler-Wysser, “Silver Thick-Film Contacts on Highly Doped N-type Silicon Emitters: Structural and Electronic Properties of the Interface,” Appl. Phys. Lett., Vol. 82, No. 12, March 2003, pp. 1878-1880.
[13] M. Van Craen, L. Frisson, and F. C. Adams, “SIMS Study of the Penetration of Metallic Secondary Impurities in Screen-Printed Silicon Solar Cells,” Surface and Interface Analysis Vol. 6, No. 6, 1984, pp. 257-260.
[14] T. Nakajima, A. Kawami, A. Tada, International Journal of Hybrid Microelectronics, vol. 6, no. 1, 1983, pp. 580-586.
[15] G. Schubert, B. Fischer, and P. Fath, “Formation and Nature of Ag Thick Film Front Contacts on Crystalline Silicon Solar Cells,” Proc. PV in Europe-From PV Technology to Energy Solutions, Rome, Italy, 2002 (in press).
[16] Gary C. Cheek, Robert P. Mertens, Roger Van Overstraeten, and Louis Frisson, “Thick-film Metallization for Solar Cell Applications,” IEEE Transactions on Electron Devices, vol. ED-31, May 1984, pp. 602-609.
[17] M. Prudenziati, L. Moro, B. Morten, F. Sirotti, and L. Sardi, “Ag-Based Thick-Film Front Metallization of Silicon Solar Cells,” Active and Passive Electronic Components, vol. 13, 1989, pp. 133-150.
[18] R. W. Olesinski and G. K. Abbaschian, Binary Alloy Phase Diagrams, edited by T. B. Massalski (American Society for Metals, Metals Park, Ohio, 1989), pp. 92-94.
[19] P. A. Basore and D. A. Clugston, “PC1D version 4 for windows: from analysis to design,” in Proc. of the 25th Photovolt. Spec. Conf., Washington, D.C., May 13-17, 1996, pp. 449-452.

### EXAMPLE 3

Now having described the embodiments of the nanostructure in general, Example 3 describes some embodiments of the nanostructure and uses thereof. The following is a non-limiting illustrative example of an embodiment of the present disclosure that is described in more detail in M. Hilali, V. Meemongkolkiat, and A. Rohatgi, “Advances in Screen-Printed High-Sheet-Resistance Emitter Cells”, Proceedings of the 13^{th} Workshop on Crystalline Silicon Solar Cell Materials and Process, Vail-Colorado, 211-214, 2003, which is incorporated herein by reference. This example is not intended to limit the scope of any embodiment of the present disclosure, but rather is intended to provide some experimental conditions and results. Therefore, one skilled in the art would understand that many experimental conditions can be modified, but it is intended that these modifications be within the scope of the embodiments of the present disclosure.

Introduction:

A combination of paste and firing conditions have been developed to achieve good ohmic contacts to 100 Ω/sq. emitters using screen-printing technology. Different dielectric front-surface passivating layers were investigated to take full advantage of the lightly-doped emitter for screen-printed cells. Using an optimum passivation layer and a simple co-firing process in a belt-furnace an absolute efficiency of 17.48% was achieved on untextured 0.6 Ω-cm FZ Si with an open-circuit voltage (V_{oc}) of 648 mV. The PV168 Ag paste in conjunction with optimum co-firing cycle resulted in a low series resistance of 0.85 Ω-cm² and a high fill factor of 0.782 on a 100 Ω/sq. emitter. Higher temperature firing to ensure Ag—Si alloying also reduced the shading losses by shrinking the gridline by about 27%.

Experimental:

Silicon solar cells were fabricated on p-type 0.6 Ω-cm FZ Si in order to enhance the influence of the emitter on V_{oc} Samples were cleaned and then diffused in a POCl₃ tube furnace to form 100 Ω/sq. emitters with a junction depth of about 0.28 μm. In order to achieve good surface passivation, the samples were coated with different dielectrics including (i) high-frequency (HF) PECVD SiNₓ, (ii) low-frequency (LF) PECVD SiNₓ, (iii) oxide/HF-PECVD SiNₓ stack, and (iv) oxide/LF-PECVD SiNₓ stack. In the case of stack passivation, about 80 Å rapid-thermal oxide (RTO) was grown prior to SiNₓ deposition. Al was screen-printed on the back and dried at about 200° C. The Ag metal grid was screen-printed on SiNₓ using PV168 paste from DuPont. All the cells were then co-fired in a lamp-heated belt furnace at a set temperature about ≧900° C. The cells were then isolated using a dicing saw followed by 400° C. forming-gas-anneal (FGA) for about 15 min. Solar cells were characterized by IV measurements and spectral response. In addition, Photoconductance Decay (PCD) technique was used to obtain Jₒₑ values for the 100 Ω/sq. emitter with different dielectrics after firing in order to decouple the impact of base and emitter region on V_{oc} and cell performance.

Results and Discussion:

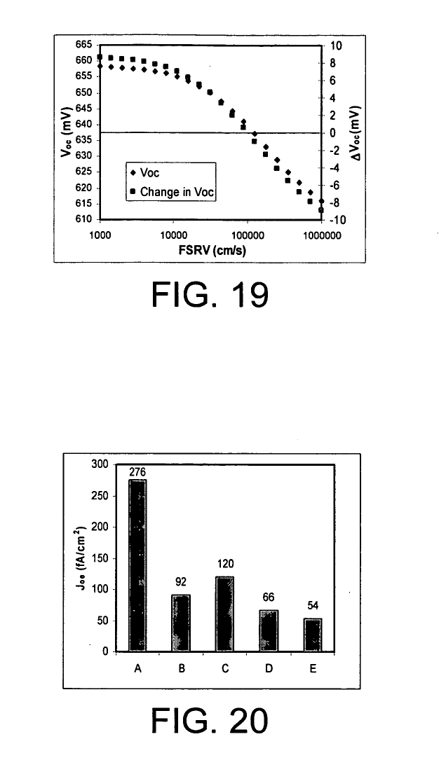

Surface Passivation of 100 Ω/sq. Emitter Due to Different Dielectrics: FIG. 19 shows the effect of FSRV on V_{oc} of 100 Ω/sq. emitter screen-printed cells. These results were obtained by model calculations using PC ID. Model calculations in FIG. 19 reveal that an FSRV above 25,000 cm/s, V_{oc} starts to decrease rapidly. The improvement in V_{oc} due to the high-sheet-resistance emitter is also shown as a function of FSRV. Notice that the V_{oc} can become worse for the 100 Ω/sq. emitter compared to the 45 Ω/sq. emitter if the front-surface passivation is very bad (>100,000 cm/s). Hence, different passivation dielectrics can be investigated on high-sheet-resistance emitters to achieve better cell performance. Table 5 shows the notation for different dielectrics used in this investigation. FIG. 20 shows the Jₒₑ values obtained by the PCD measurements [2] for the 100 Ω/sq. emitter passivated with these five dielectrics. Jₒₑ is highest for HF-SiNₓ (A) and lowest for the LF-SiNₓ and stack passivation (D and E, respectively). It is important to note that these Jₒₑ measurements reveal the passivation quality of the dielectric without the metal contact.

TABLE 5
Notation for different passivating
dielectrics used in this study.

| Label | Description of Passivating Dielectric |
|---|---|
| A | HF PECVD SiNₓ |
| B | Stack HF PECVD SiNₓ/RTO |
| C | LF PECVD SiNₓ with no NH₃ clean |
| D | LF PECVD SiNₓ with NH₃ clean |

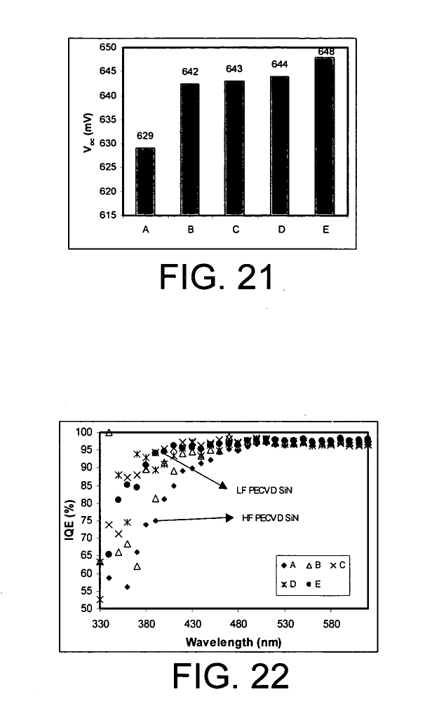

In order to compare the effect of each passivating dielectric on the cell performance, IV and IQE measurements were performed. FIG. 21 shows the V_{oc} of the cells with different passivating layers. As expected from the Jₒₑ measurements, the highest V_{oc} (648 mV) was obtained for the LF-SiNₓ/RTO stack and the lowest V_{oc} (629 mV) for the HF-SiNₓ. Recall that low resistivity FZ was used to lower the J_{ob} value and make V_{oc}, more sensitive to Jₒₑ [3]. The measured bulk lifetime of the 0.6 Ω-cm FZ Si cells was 250 μs, indicating that high bulk lifetime is maintained during the belt-line processing. IQE measurements showed that the long-wavelength response of the cells was independent of dielectric passivation; however, FIG. 22 shows that the short-wavelength response was quite sensitive to the dielectric passivation. The best blue response was obtained for passivation layers E and D (LF-SiNₓ and stack). The HF-SiNₓ passivation exhibited the poorest blue response.

Reduction in Shading and Metal Resistivity Compared to Conventional Paste and Firing: FIG. 23 shows magnified images of (a) as-dried screen-printed PV168 Ag gridline, (b) alloyed PV168 gridline, and (c) conventional paste-A gridline fired at about 750° C., which is below the Ag—Si eutectic temperature. The PV168 paste was alloyed using fast firing in the belt-line furnace at a set temperature ≧900° C. It was found that the metal resistivity of paste-A Ag grid was about 2.8 μΩ-cm while the resistivity of the alloyed PV168 Ag grid was about 1.9 μΩ-cm, which is quite close to the resistivity of pure Ag (1.7 μΩ-cm). The alloyed PV168 Ag grid shrank from about 102 μm to about 74 μm after firing which amounts to a 27% reduction in gridline width. This is consistent with the more compact structure and lower metal resistivity of the PV168 grid. The gridline width was about 110 μm for paste A after the conventional firing between 700-800° C.

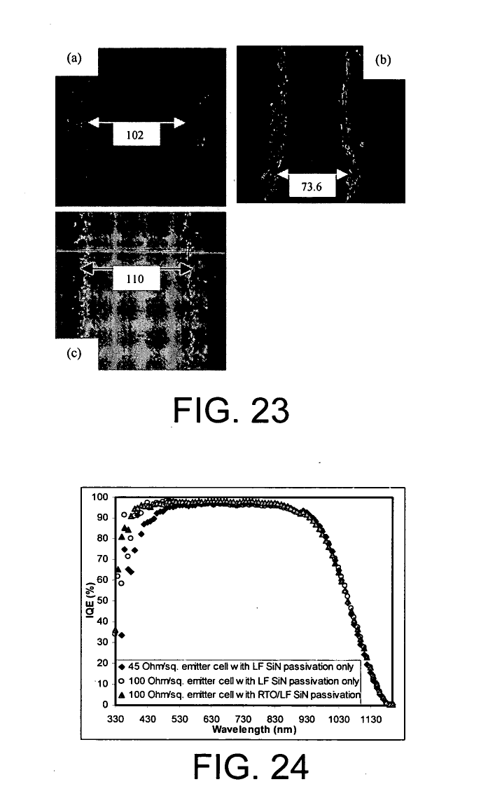

High Efficiency Screen-Printed Cells on 100 Ω/sq. Emitter with Optimized Front-Surface Passivation and Grid Design: In addition to the optimization of the surface passivation, grid design was also optimized for the 100 Ω/sq. emitter. Table 6 shows the improvement in cell performance due to better front-surface passivation along with the improvement due to optimal grid design. On the 100 Ω/sq. emitter, a high FF of 0.782 was achieved for the LF-SiNₓ passivating layer and 0.777 for the stack passivation. The LF-SiNₓ passivated cell had a V_{oc} of 643 mV, which is significantly higher than the HF-SiNₓ passivated cell with a V_{oc} of 629 mV. This enhancement in V_{oc} is in good agreement with the Jₒₑ measurements. In the case of the bad passivation using HF-SiNₓ, the V_{oc} for the 45 Ω/sq. emitter was 635.8 mV, which is greater than that for the 100 Ω/sq.-emitter cell (629.3 mV). These results agree with the model calculations in FIG. 19, which show that the V_{oc} of a low sheet-resistance-emitter cell can be higher than that of a high-sheet-resistance emitter cell in the case of bad passivation. Moreover, by optimizing the gridline spacing (0.2 cm instead of 0.24 cm) for the 100 Ω/sq. emitter, the series resistance dropped to 0.85 Ω-cm² as compared to 1.06 Ω-cm² and the FF increased from 0.771 to 0.782. Notice that in this study, very high fill factors of 0.793 were achieved on the conventional 45 Ω/sq.-emitter cell. By considering LF-SiNₓ only, Table 6 shows that the short-circuit current (J_{sc}) was highest for the stack passivation (34.69 mA/cm²), followed by the SiNₓ passivation only (34.48 mA/cm²). The J_{sc} was lowest for the 45 Ω/sq. emitter (34.07 mA/cm²). The V_{oc} showed the same trend. Consequently, the well-passivated high-sheet-resistance emitter gave 0.2% improvement in the absolute efficiency over the conventional 45 Ω/sq. emitter, in spite of the slightly lower FF. FIG. 24 shows that the short-wavelength IQE of the 100 Ω/sq.-emitter cell is superior to that of the 45 Ω/sq.-emitter cell. At 410 nm, the IQE was 82.38% for 45 Ω/sq. emitter compared to 92.137% for the LF-SiNₓ passivated 100 Ω/sq. emitter. All these improvements resulted in 17.5% efficient screen-printed planar cells on FZ Si with 100 Ω/sq. emitters.

TABLE 6
Cell IV data for the 45 and 100 Ω/sq. emitters showing performance improvement
due to passivation and grid design. PV168 Ag paste is used in all the cases.

| Front Passivation | Grid Design | Emitter | V_{oc} (mV) | J_{sc} (mA/cm²) | FF | Eff (%) | n factor | Rₛ (Ω-cm²) | Rₛₕ (Ω-cm²) |
|---|---|---|---|---|---|---|---|---|---|
| HF PECVD SiN | Optimized | 45 | 635.8 | 33.32 | 0.788 | 16.70 | 1.01 | 0.762 | 8572 |
| LF PECVD SiN | Optimized | 45 | 637.5 | 34.07 | 0.793 | 17.22 | 1.07 | 0.696 | 38,453 |
| HF PECVD SiN | Unoptimized | 100 | 629.3 | 34.2 | 0.774 | 16.67 | 0.99 | 1.08 | 10,875 |
| LF PECVD SiN | Unoptimized | 100 | 643.0 | 34.49 | 0.771 | 17.10 | 1.03 | 1.065 | 496,500 |
| LF PECVD SiN | Optimized | 100 | 646.1 | 34.48 | 0.782 | 17.42 | 1.08 | 0.854 | 131,404 |
| Stack (LF SiN/RTO) | Optimized | 100 | 648.4 | 34.69 | 0.777 | 17.48 | 1.08 | 0.919 | 75,306 |

Conclusion:

In this example, high quality screen-printed contacts were achieved on 100 Ω/sq. emitters using PV168 Ag paste and rapid co-firing in the belt furnace. Different emitter passivating dielectrics were investigated. Low-frequency SiNₓ and the stack passivation with RTO/SiNₓ were found to be very effective, resulting in a V_{oc} of 648 mV. Using this simple and fast contact co-firing scheme using the PV168 paste, FFs of 0.793 were achieved on 45 Ω/sq. emitters and 0.782 on 100 Ω/sq emitters. In addition, the alloyed PV168 paste showed about 27% shrinkage after firing, resulting in gridline width of 74 μm. The 100 Ω/sq. emitter also showed an appreciable improvement in the blue-response over the conventional 45 Ω/sq. emitter, resulting in 0.2% improvement in absolute efficiency in spite of slightly lower FF. Somewhat lower emitter sheet resistance (80-100 Ω/sq.) are now being investigated to recover the FF loss without sacrificing the blue response.

### REFERENCES

[1] M. Hilali, J.-W. Jeong, A. Rohatgi, D. L. Meier, and A. F. Carroll, “Optimization of Self-Doping Ag Paste Firing to Achieve High Fill Factors on Screen-Printed Silicon Solar Cells with a 100 Ω/sq. Emitter,” Proc. of the 29th IEEE PVSC, New Orleans, May 2002, pp. 356-359.
[2] D. MacDonald, A. Cuevas, “Trapping of Minority Carriers in Multicrystalline Silicon,” Appl. Phys. Lett., vol. 74, no. 12, 1999, pp. 1710-1712.
[3] A. Rohatgi, M. Hilali, D. L. Meier, A. Ebong, C. Honsberg, A. F. Carroll, and P. Hacke, “Self-Aligned Self-Doping Selective Emitter for Screen-Printed Silicon Solar Cells,” Proc. of the 17^{th} European Solar Energy Conference, Munich, 2001, pp. 1307-1310.

### EXAMPLE 4

Now having described the embodiments of the nanostructure in general, Example 4 describes some embodiments of the nanostructure and uses thereof. The following is a non-limiting illustrative example of an embodiment of the present disclosure that is described in more detail in A. Upadhyaya, K. Nakayashiki, M. Hilali, A. Rohatgi, J. Kalejs, B. Bathey, K. Matthei “RECORD HIGH EFFICIENCY SCREEN-PRINTED BELT CO-FIRED CELLS ON EFG Si RIBBON (16.1%) AND HEM mc-Si (16.9%)”), in Proceedings of the 13^{th} Workshop on Crystalline Silicon Solar Cell Materials and Process, Vail, Colorado, pp. 215-218, 2003, which is incorporated herein by reference. This example is not intended to limit the scope of any embodiment of the present disclosure, but rather is intended to provide some experimental conditions and results. Therefore, one skilled in the art would understand that many experimental conditions can be modified, but it is intended that these modifications be within the scope of the embodiments of the present disclosure.

Introduction:

Record high efficiency screen-printed solar cells have been fabricated on EFG Si ribbon as well as on HEM mc-Si. These cells were fabricated using a process involving POCl₃ diffusion for emitter and rapid co-firing of Ag grid and Al-BSF in a belt furnace. This resulted in very effective defect passivation and good contacts with low series resistance and junction leakage. Average bulk lifetimes in the range of 80-100 μs were achieved after cell processing along with Fill Factors of about 0.78. The EFG Si cells were fabricated on a 95±5 Ω/sq. emitter while the HEM mc-Si cells were fabricated on 45±5 Ω/sq. emitter. A combination of good ohmic contacts, effective back surface field, and high bulk lifetimes resulted in record high 16.1% efficient screen-printed cells on EFG Si and 16.9% on HEM mc-Si.

Discussion:

High Efficiency Screen-printed Selective Emitter Cells on EFG Silicon: EFG Si ribbon is a promising material for low-cost and high-efficiency solar cells because it can eliminate the need for mechanical sawing and damage etching. As a result, there is no kerf loss. However, like most low-cost mc-Si materials, the EFG material also has high impurity concentrations and crystalline defect density. The as-grown minority-carrier lifetime in EFG is quite low, normally less than 3 μs, which is not sufficient for high efficiency cells. It is essential to enhance the bulk minority-carrier lifetime of EFG during cell fabrication in order to obtain high efficiency cells (>15%). This example reports on the implementation of a fast co-firing process for front and back contacts which significantly enhances the bulk lifetime in EFG and simultaneously produces high quality screen-printed contacts on high-sheet-resistance (95±5 Ω/sq.) emitter. The process is very simple, manufacturable, and capable of producing high efficiency screen-printed cells.

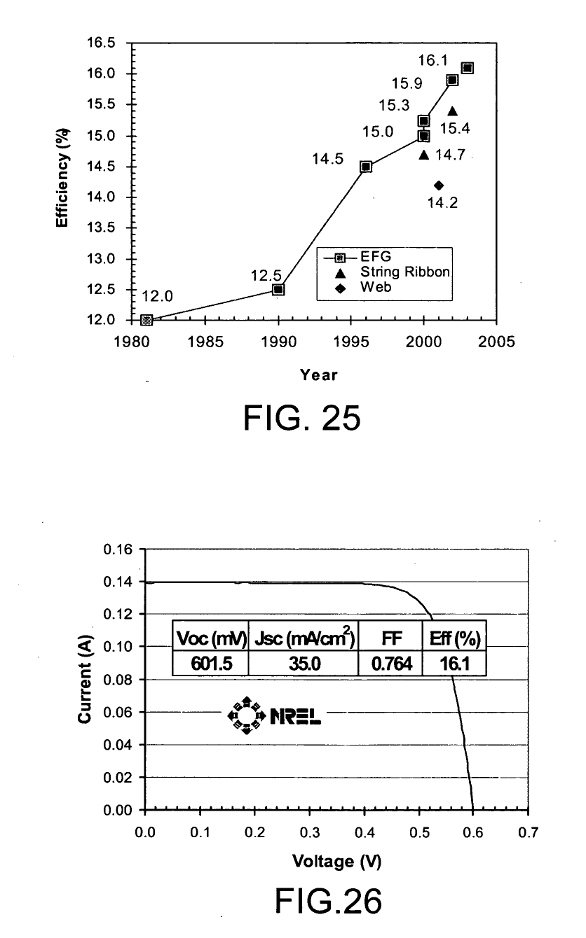

FIG. 25 shows the progress of screen-printed or pad-printed silicon ribbon solar cells. Previous record of 15.9% involved a two-step firing in an RTP system using 45±5 Ω/sq. emitter [1]. In this example, 16.1% efficient 4 cm² cells were achieved by a co-firing process on a 95±5 Ω/sq. emitter using screen-printing technology and a belt line furnace. A simple n⁺-p-p⁺ cell design was used in conjunction with 2-3 Ω-cm, 300 Ωm thick EFG Si grown at RWE Schott Solar, Inc. Cell fabrication involved phosphorus diffusion in a POCl₃ furnace to form about 100 Ω/sq. emitter. A SiNₓ AR coating with an average refractive index of about 2.04 and thickness of about 760 Å was deposited on top of the n⁺ emitter in a commercial low-frequency plasma enhanced chemical vapor deposition (PECVD) reactor. A commercial Al paste was printed on the entire backside and dried at 200° C. The front-metal grid was then screen-printed on top of the SiNₓ AR coating using PV168 Ag paste from DuPont Corporation. The sample was then co-fired rapidly in a three-zone lamp-heated belt-furnace at set temperature ≧875° C. and belt speed >80 ipm to form the Al back-surface field (BSF) and front grid metallization, simultaneously. The firing process is similar to the one reported in [2] involving fast ramp-up and cooling rates to promote and enhance PECVD SiNₓ-induced hydrogen passivation of defects in EFG Si [3,4]. Finally, cells were annealed in forming gas at 400° C. for 15 mm.

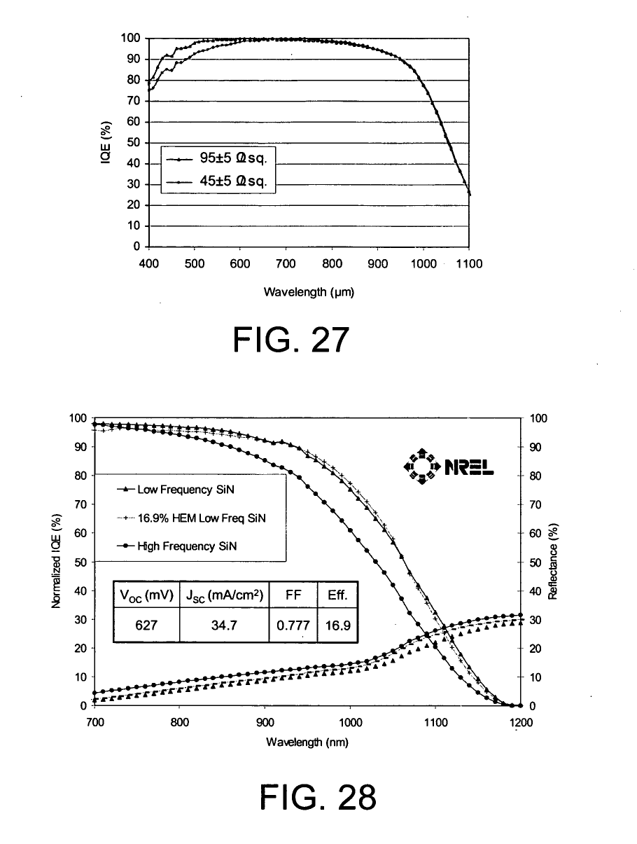

FIG. 26 shows the lighted I-V data for the 16.1% efficient EFG Si cell (verified by National Renewable Energy Laboratory). This cell had an open-circuit voltage (V_{oc}) of 601.5 mV, short-circuit current (J_{sc}) of about 35.0 mA/cm², and a fill factor (FF) of 0.764. Moreover, the average cell efficiency was 15.73% with a standard deviation of 0.28%. This firing scheme achieved a low contact resistance value of 0.77 Ω-cm² on 95 Ω/sq. emitter while reducing the junction shunting resulting in a FF of about 0.764. The fast contact co-firing in the belt-furnace helped in achieving very effective defect hydrogenation. This is supported by very high average lifetime of about 103 μs in EFG Si with standard deviation of 43 μs. In addition, FIG. 27 shows the improvement in the short wavelength response due to the lightly doped emitter compared to the conventional 45 Ω/sq. emitter cell. All these improvements contributed to the record high efficiency (16.1%) EFG Si cell.

High Efficiency Screen-printed Cells on HEM mc-Si: Like EFG Si ribbon, HEM mc-Si grown by a cast technique is also a promising low-cost material for cost effective PV. HEM is widely used in industry with commercial cell efficiency in the range of 13.5-15.0%. Efficiencies as high as 16.6% have been reported on 156 cm² cast mc-Si material using screen-printing, single layer SiNₓ AR coating, isotropic texturing and selective emitter. [5] In this example, 4 cm² 16.9% screen-printed, belt co-fired cells with single layer SiNₓ AR coating are discussed. These cells do not have any texturing, double layer AR coating, or selective emitter. The process is simple and manufactuable, involving POCl₃ diffusion to form 45 Ω/sq. emitter, followed by SiNₓ AR coating on the front, Ag grid printing on the front using commercial paste from DuPont Corp., Al screen-printing on the back, and a rapid firing in the belt furnace. Finally, cells are annealed at 400° C./15 min in forming gas.

FIG. 28 shows the cell data for the 16.9% efficient HEM cell, tested and verified by NREL. This cell had an open circuit voltage of 627 mV, short circuit current of 34.7 mA/cm², and fill factor of 0.777. Nine 4 cm² cells on a large area wafer had an average efficiency of 16.5%.

Hydrogenation from low frequency PECDV SiNₓ played an important role in efficiency enhancement. This is reflected in the long wavelength IQE response of the HEM cells with high frequency (13.6 MHz) and low frequency (50 kHz) PECVD SiNₓ. Low frequency SiNₓ significantly improves the long wavelength response of the cells. This is attributed at least in part to the effective hydrogenation of defects due to rapid firing in conjunction with the use of low frequency SiNₓ. PCD lifetime measurements showed that the 20-40 μs as-grown lifetime in the HEM mc-Si increased to about 100 μs after the cell processing.

Conclusions:

Record high efficiency screen-printed solar cells have been achieved on EFG Si (16.1%) and HEM mc-Si (16.9%). This is the result of appropriate rapid co-firing of Ag grid, Al-BSF, and SiNₓ AR coating which results in very effective defect hydrogenation, good back surface field, and high quality screen-printed contacts. Bulk lifetimes approaching 100 μs were achieved with fill factors of about 0.78.

### REFERENCES

[1] Ajeet Rohatgi and Ji-Weon Joeng, J. Appl. Phys., 82, 224 (2003)
[2] M. Hilali, J. W. Jeong, A. Rohatgi, D. L. Meier, and A. F. Carroll, Proceedings of 29^{th} IEEE Photovoltaic Specialists Conference, New Orleans, La., 2002, (IEEE, New York, 2002), p. 356
[3] A. Rohatgi, V. Yelundur, J. Jeong, A. Ebong, M. D. Rosenblum, and J. I. Hanoka, 12^{th} International Photovoltaic Science and Engineering Conference, Jeju, S. Korea, 2001, 23-1 (invited paper)
[4] J. Jeong, Y. H. Cho, A. Rohatgi, M. D. Rosenblum, B. R. Bathey, and J. P. Kalejs, Proceedings of 29^{th} IEEE Photovoltaic Specialists Conference, New Orleans, La., 2002, (IEEE, New York, 2002), p. 250
[5] J. Szlufcik, F. Duerinckx, E. V. Kerschaver, J. Nijs, Proceedings of 17^{th} European Photovoltaic Solar Energy Conference, Munich, Germany, 2001, pp. 1271-1276.

### EXAMPLE 5

Now having described the embodiments of the nanostructure in general, Example 5 describes some embodiments of the nanostructure and uses thereof. The following is a non-limiting illustrative example of an embodiment of the present disclosure that is described in more detail in K. Nakayashiki, V. Meemongkolkiat, and A. Rohatgi “Record High Efficiency Solar Cells on EFG (18.2%) and String Ribbon (17.8%) Silicon by rapid thermal processing,” in Proceedings of the 13^{th} Workshop on Crystalline Silicon Solar Cell Materials and Process, Colorado, pp. 219-223, 2003, which is incorporated herein by reference. This example is not intended to limit the scope of any embodiment of the present disclosure, but rather is intended to provide some experimental conditions and results. Therefore, one skilled in the art would understand that many experimental conditions can be modified, but it is intended that these modifications be within the scope of the embodiments of the present disclosure.

Introduction:

Record high silicon ribbon solar cell efficiencies of 18.2% and 17.8% were achieved on EFG and String Ribbon silicon, respectively. These cells were fabricated with photolithography front contacts and double layer antireflection coating. Improved understanding and hydrogenation of defects in these promising low-cost ribbon materials contributed to the significant increase in bulk lifetime from 1-5 μs to as high as 90-100 μs during cell processing. It was found that SiNₓ-induced defect hydrogenation in these ribbon materials takes place within one second at peak temperatures of 740-750° C. In fact, bulk lifetime decreases with the increase in annealing temperature above 750° C. or annealing time in excess of one second due to the enhanced dissociation of the hydrogenated defects coupled with the decrease in hydrogen supply from the SiNₓ film.

Experimental:

String Ribbon and EFG samples used in this study had an average thickness of 300 μm and resistivity of 3 Ωcm. P-type EFG ribbon was grown at ASE Americas while String Ribbon was grown at Evergreen Solar, respectively. The phosphorus diffusion was performed using a liquid POCl₃ source in a tube furnace to obtain an 85 Ω/cm n⁺-emitter. SiNₓ film with a thickness of 78 nm and index of 2.0 was deposited in a commercial low-frequency PECVD reactor on the phosphorus-diffused emitter. Aluminum paste (Ferro FX 53-038) was screen-printed on the back surface of the wafers. The SiNₓ on the front and the Al on the rear were fired simultaneously in an RTP chamber to enhance hydrogen passivation. The ramp-up and cooling rates were set to greater than 50° C./sec to achieve a uniform Al-BSF layer and provide good hydrogenation. The firing temperatures were varied from 700 to 800° C.ⁱ,ⁱⁱ and firing time from 1 to 60 seconds to understand and optimize the hydrogenation of defects and quality of BSF simultaneously. The front metal grid was defined by a photolithography process involving etching of the SiNₓ film in BOE (buffered oxide etchant). Front contacts were then formed by evaporating 60 nm Ti, 40 nm Pd and 60 nm Ag followed by a lift-off process. Additional Ag was plated to increase the grid thickness to about 8 μm and reduce the series resistance to about 0.5 Ω-cm². Nine 4 cm² cells were fabricated on each wafer and isolated using a dicing saw followed by a 30 min forming gas anneal at 400° C. In order to minimize the reflectance, the SiNₓ thickness was adjusted to 67.8 nm and capped with 99.5 nm magnesium fluoride film by vacuum evaporation to form a DLAR, which reduced the integrated front surface reflectance to about 6.19%.

Results and Discussion:

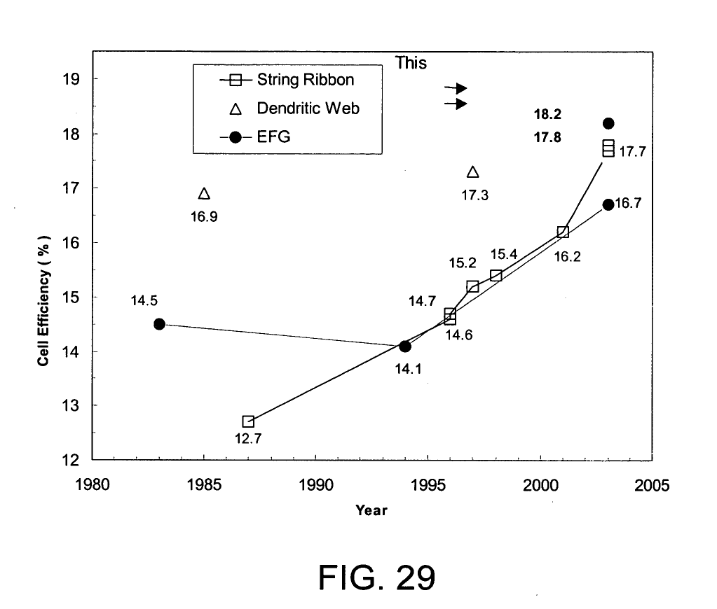

FIG. 29 shows the progress in efficiency of ribbon solar cells with photolithography contacts. Data for Dendritic Web and EFG cells with photolithography (PL) contacts is limited. Cell efficiencies of about 17% have been reported on Dendritic Web Si in the past, whereas relatively steady progress has been made on String Ribbon cells with PL contacts with maximum efficiency of 16.2% in 2001. This example reports on record high efficiencies of 18.2% on EFG and 17.8% on String Ribbon. These 4 cm² cells were tested and verified by NREL, demonstrating the potential of these ribbon materials.

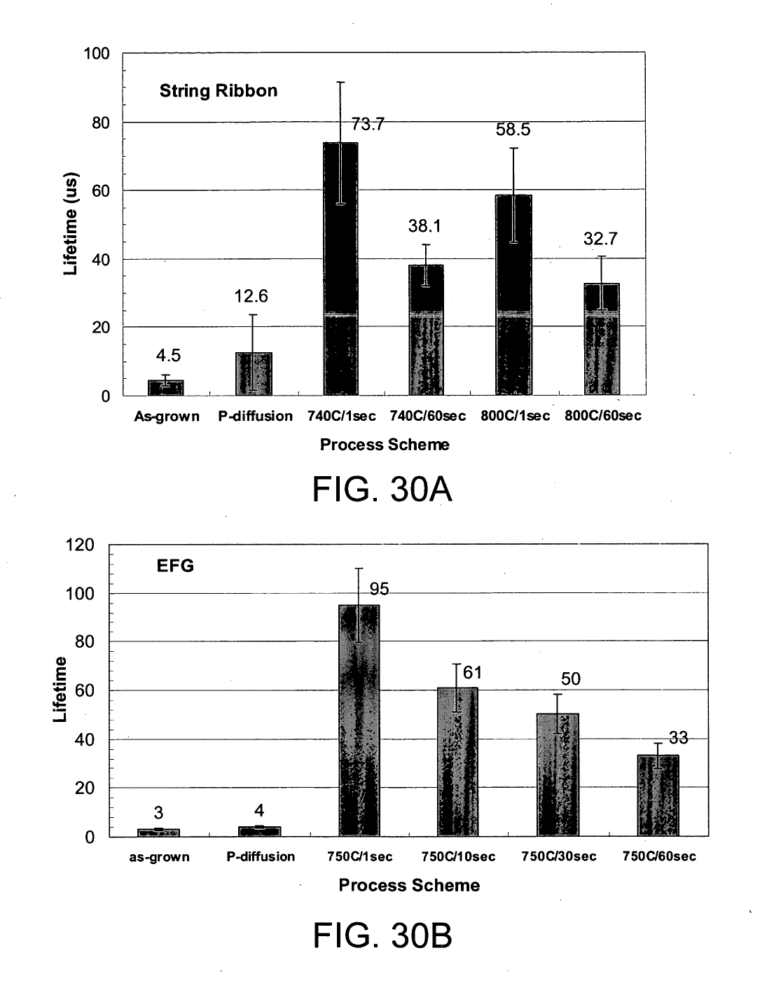

FIGS. 30A and 30B shows the process-induced lifetime enhancement in these materials. The as-grown bulk lifetime was in the range of 2-5 μs, which increased to 4-15 μs range after the 85 Ω/cm phosphorus emitter diffusion. The bulk lifetime improved significantly after the SiNₓ/Al co-firing in the RTP chamber without the need for any additional or extra gettering step. In this study, lifetime enhancement was found to be very sensitive to the co-firing time and temperature. Average bulk lifetime increased from 4.5 μs to 73.7 μs in String Ribbon and from 3 μs to 95 μs in EFG with only one second RTP firing at about 750° C. One second firing maintained bulk lifetime over 50 μs even at 800° C. whereas bulk lifetime dropped rapidly to 33 μs at 750° C. for 60 second firing. This indicates that hydrogen diffusion into silicon and bulk defect passivation by the hydrogen take place in a very short time. Optimum co-firing condition was found to about 750° C./1 s. FIGS. 30A and 30B clearly show that defect passivation or bulk lifetime enhancement degrades at higher co-firing temperature (>750° C.) or longer time (>1 second). The low starting lifetime in String Ribbon and EFG Si is the result of high dislocation density and metal impurities. It has been reported that hydrogenated metal defects dissociate during high temperature annealing with activation energies in the range of about 2.2 to 2.5 eV. This can give rise to deep levels. The dissociation energy for the hydrogenated dislocation related Si—H bonds reported to be about 2.6 to 3.5 eV. Therefore, if hydrogen diffusion or supply into the silicon stops, the fraction of reactivated defects (N/Nₒ) can be described by the equation:

$$\frac{N}{{N}_{0}} = 1 - exp [ - tv exp ( - {E}_{d} / kT ) ] \qquad ( 1 )$$

where t is the annealing time, v is attempt frequency (10¹³ to 10¹⁴/s), E_{d} is the activation energy for the reactivation process and T is the temperature. Calculations reveal that 63% of passivated metal defects can re-activated in just 0.055 second at 740° C. assuming v=5×10¹³/s and E_{d}=2.5 eV. In contrast, it should take 53 second to re-activate 63% of the hydrogenated dislocations, using an activation energy of about 3.1 eV and v=5×10¹³/s. In order to maximize the bulk lifetime, the dehydrogenation process should be quenched after the defects are saturated with hydrogen. It has been shown that the Si—H concentration in the SiNₓ film decreases rapidly within 20 seconds down to the detection limit at temperatures above 700° C., while the N—H concentration decreases rapidly followed by a slower decrease. This suggests that the supply of hydrogen from the SiNₓ film or the hydrogen flux into the silicon decreases rapidly within the first 20 seconds and then decrease slowly. However, the activation of defect continues with time and its rate increases with temperature (equation 1). This explains the observed decrease in bulk lifetime with the increase in firing time or temperature (FIGS. 30A and 30B). In order to support the rapid activation rate, the SiNₓ film was removed after the hydrogenation at 740° C./1 s to stop the hydrogen supply and then re-annealed the sample at 740° C. It was found that in the absence of hydrogen supply it only took 2 seconds to activate the defects and the lifetime dropped from 74 μs to 9 μs.

Hydrogen diffusion into a defective silicon can be influenced by defects type and concentration, in addition to temperature, doping density and conductivity type. For example, it has been shown that hydrogen can diffuse rapidly via dislocations. On the other hand, the hindrances to hydrogen diffusion have been reported in single crystalline silicon at low temperature. In p-type Si, most of the hydrogen diffuses by rapid interstitial motion at high temperature over 500° C., without any retardation by either acceptor trapping or molecule formation. Van Weirengen and Warmoltz measured the interstitial hydrogen diffusivity in the temperature range of 1090 to 1200° C. given by

$${D}_{H } = 9.4 \times {10}^{- 3} exp ( \frac{- 0.48 eV}{kT} ) {cm}^{2} \text{/} s . \qquad ( 2 )$$

However, the experimental results on diffusivity measurements at lower temperature have given smaller values than the extrapolated VWW data. The extrapolation of the VWW data yields a diffusivity of 4.0582×10⁻⁵ cm²/s at 750° C. Substantial improvement in the bulk lifetime (85 to 95 μs) coupled with significant increases in the long IQE response for the EFG and String Ribbon cells after one second firing indicates that the defect passivation by hydrogen is accomplished throughout entire 300 μm thick wafers within one second. A Simple x=(Dt)^{1/2} approximation gives 9×10⁻⁴ cm²/s, assuming that hydrogen diffuses through a 300 μm thick wafer in 1 second at 750° C. This is a factor of twenty times higher than the extrapolated interstitial diffusivity from VWW data. Using a 5 second thermal budget above 500° C. associated with the ramp-up and ramp-down gives a diffusivity of 1.8×10⁻⁴ cm²/s, which is still 4 times higher than the VWW's diffusivity at 750° C. This suggests that effective hydrogen diffusion may be enhanced by mechanisms other than interstitial diffusion. Ribbon materials contain high dislocation concentration (10⁵ to 10⁶/cm²), which could accelerate the movement of hydrogen through the bulk. It was shown by Dubeⁱ that hydrogen diffuses more rapidly along the dislocations than grain boundaries or intragrain single crystal regions. Furthermore, it has been suggested that the dislocations and vacancies can increase the hydrogen solubility by dissociating H₂ molecules into atomic hydrogen. Ribbon materials have high concentration of vacancies, which are introduced into the bulk during the ribbon growth or cell processing steps such as Al-BSF formation and SiNₓ deposition. It has been suggested that vacancies can enhance hydrogen diffusion and defect passivation by providing additional driving force for diffusion or by dissociating H₂ molecules. In addition, light-enhanced hydrogen release from Si—H bonds or strain-enhanced H₂ molecule dissociation has been suggested, which could increase the hydrogen diffusion in our experiment since intense illumination is used in RTP to heat the wafers and stress is introduced during the Al-BSF process. Sopori et. al. used computer simulation to show that hydrogen can diffuse through a 100-μm thick wafer after a 10-second annealing of SiNₓ coated wafers at 800° C. in an RTP chamber. Thus, very rapid and effective hydrogenation of defects observed in ribbon materials seems to be the result of multiple effects that tend to enhance hydrogen diffusion or concentration.

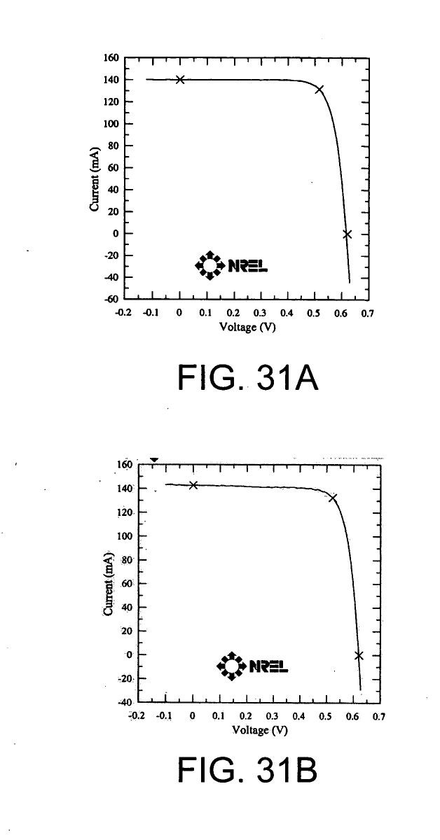

Based on the above understanding and experimental data, optimum hydrogenation conditions (about 750° C./Is) were used (FIGS. 30A and 30B) to fabricate ribbon cells. FIGS. 31A and 31B shows the light I-V characteristics of the record high efficiency cells achieved on EFG and String Ribbon silicon. The 18.2% cell on EFG and 17.8% cell on String Ribbon were tested and verified by NREL. The cells had Voc of about 620 mV and FF of 0.78. The J_{sc} for EFG and String Ribbon were of about 37 mA/cm² and 36.8 mA/cm², respectively. These results are consistent with very high bulk lifetimes approaching 100 μs and double layer AR coating.

In conclusion, ribbon silicon solar cells with efficiency of 18.2% on EFG and 17.8% on String Ribbon were achieved, supporting the potential of ribbon materials. It was found that effective defect hydrogenation in ribbon materials takes place within 1 second at 740 to 750° C. Bulk lifetimes approaching 100 μs were achieved. The bulk lifetime was found to decrease with the increase in annealing temperature above 750° C. and annealing time over 1 second due to the decrease in hydrogen supply from the SiNₓ film and continued dissociation of the hydrogenated defects. These cell results with photolithography contacts and double layer AR coating suggest that 16-17% efficient manufacturable ribbon cells can be realized with screen printed Ag contacts and single layer SiNₓ AR coating.

### REFERENCES

A. Rohatgi, V. Yelundur, J-W. Jeong, D. S. Kim, A. M. Gabor, The Third World Conference on Photovoltaic Energy Conversion, Osaka, Japan, 2003, in press.
J-W. Jeong, M. D. Rosenblum and J. P. Kalejs, A. Rohatgi, J. Appl. Phys., 87, 7551(2000).
R. O. Bell and J. P. Kalejs, J. Mater. Res., 13, 2732(1998).
S. J. Pearton, J. W. Corbett, and T. S. Shi, Appl. Phys. A, 43, 153(1987).
C. K-Kemmerich, W. Beyer, J. Appl. Phys., 66, 552(1989).
W. L. Hansen, E. E. Haller and P. N. Luke, IEEE Tran. on Nucl. Sci., NS-29, 738(1982).
G. V. Gadiyak, V. G. Gadiyak, M. L. Kosinova, E. G. Salman, Thin Solid Films, 335, 19(1998).
C. Dube and J. I. Hanoka, Appl. Phys. Lett. 45, 1135(1984).
J. Pearton, W. Corbett and M. Stavola, Hydrogen in crystalline semiconductors (Springer-Verlag Heidelberg New York), 1991.
A. Van Wieringen and N. Warmoltz, Physica (Netherlands), 22, 849(1956).
D. Mathiot, Phys. Rev. B, 40, 5867(1989).
T. Zundel, J. Weber, Phys. Rev. B, 46, 2071(1992).
C. H. Seager, R. A. Anderson, D. K. Brice, J. Appl. Phys., 68, 3268(1990).
S. Bedard, L. J. Lewis, Phys. Rev. B, 61, 9895(2000).
C. Dube and J. I. Hanoka, Appl. Phys. Lett. 45, 1135(1984).
C. K. Kemmerich, W. Beyer, J. Appl. Phys., 66, 552(1989).
S. K. Estreicher, J. L. Hastings, P. A. Fedders, Phys. Rev. B, 57, R12663(1998).
J-W. Jeong, M. D. Rosenblum, J. P. Kalejs, and A. Rohatgi, J. Appl. Phys., 87, no. 10, 7551(2000).
A. Rohatgi, V. Yelundur, J. Jeong, A. Ebong, M. D. Rosenblum, J. I. Hanoka, Sol. Energy Mater. & Sol. Cells, 74, 117(2002).
B. L. Sopori, K. Jones, X. J. Deng, Appl. Phys. Lett., 61, 2560(1992).
M. A. Roberson, S. K. Estreicher, Phys. Rev. B, 49, 17040(1994).
O. Greim, J. Weber, Y. Baer, Phys. Rev. B, 50, 10644(1994).
S. K. Estreicher, J. L. Hastings, P. A. Fedders, Phys. Rev. B, 57, R12663(1998).
B. L. Sopori, Y. Zhang, and R. Reedy, “H diffision for impurity and defect passivation: a physical model for solar cell processing”, Proceedings of the 29th Photovoltaic Specialists Conference (IEEE, New Orleans, 2002) p. 222.

### EXAMPLE 6

Now having described the embodiments of the nanostructure in general, Example 6 describes some embodiments of the nanostructure and uses thereof. The following is a non-limiting illustrative example of an embodiment of the present disclosure that is described in more detail in D. S. Kim, *A. M. Gabor, V. Yelundur, A. D. Upadhyaya, V. Meemongkolkiat, A. Rohatgi “STRING RIBBON SILICON SOLAR CELLS WITH 17.8% EFFICIENCY”, Proceedings 3^{rd} World Conference on Photovoltaic Energy Conversion, Vol. B, pp. 1293-1296, May 11-18, 2003, which is incorporated herein by reference. This example is not intended to limit the scope of any embodiment of the present disclosure, but rather is intended to provide some experimental conditions and results. Therefore, one skilled in the art would understand that many experimental conditions can be modified, but it is intended that these modifications be within the scope of the embodiments of the present disclosure.

Introduction:

4 cm² cells on String Ribbon Si wafers with efficiencies of 17.8% using a combination of laboratory and industrial processes were fabricated. These are the most efficient String Ribbon devices made to date, demonstrating the high quality of the processed silicon and the future potential for industrial String Ribbon cells. Co-firing PECVD (Plasma Enhanced Chemical Vapor Deposition) silicon nitride (SiNₓ) and Al was used to boost the minority carrier lifetime of bulk Si. Photolithography front contacts were used to achieve low shading losses and low contact resistance with a good blue response. The firing temperature and time were studied with respect to the trade-off between hydrogen retention and aluminum back surface field (Al-BSF) formation. Bulk defect hydrogenation and deep Al-BSF formation took place in a very short time (about 1 sec) at temperatures higher than 740° C.

Experimental:

Standard String Ribbon wafers were pulled from the Evergreen production line with an average thickness of 300 μm and a resistivity of 3 Ωcm. P-type, 300 μm thick, 2 Ωcm FZ wafers were also used in this study. The String Ribbon silicon wafers were cut to an optimum size for tube diffusion and cleaned/etched in cleaning solutions of 2:1:1H₂O:H₂O₂:H₂SO₄, 15:5:2 HNO₃: CH₃COOH:HF, 2:1:1H₂O:H₂O₂:HCl. The phosphorus diffusion was performed at 870° C. for 32 minutes using a liquid POCl₃ source in a tube furnace to obtain an 85 Ω/cm n⁺ emitter. The SiNₓ films were deposited by PECVD at Evergreen Solar on the phosphorus-diffused emitters. Aluminum paste (Ferro FX 53-038) was screen-printed on the back surface of the wafers. The SiNₓ on the front and the Al film on the rear were fired simultaneously in an RTP chamber to enhance hydrogen passivation. The ramp-up and cooling rates were set to >50° C./sec for all the firing processes to achieve a uniform Al-BSF layer [5]. The firing temperatures were varied from 700 to 800° C. for 1 second and 60 seconds in order to study the effects of firing temperature and time on the cell performance. The range of firing temperatures used in this study was determined from optimization of screen-printed String Ribbon solar cells, also being presented at this conference [6]. The processing temperature was measured by a thermocouple in physical contact with the front side of wafer. The front metal grid was defined by a photolithography process followed by removal of the SiNₓ film in the grid region by etching in HF. Front contacts were formed by evaporating 60 nm Ti, 40 nm Pd and 60 nm Ag followed by a lift-off procedure. Additional Ag was plated to increase grid thickness and reduce series resistance. Nine 4 cm² cells on each wafer were isolated using a dicing saw and then annealed in forming gas (4% hydrogen in nitrogen) for 30 min. Emitter saturation current density (Jₒₑ) was measured by Sinton's PCD method. Optical properties of the SiNₓ were characterized using a spectroscopic ellipsometer (J.A. Woollam Co., Inc.) to determine the optimal design of a double layer antireflection coating. In order to minimize reflectance, the SiNₓ thickness was adjusted to 67.8 nm by etching the film in HF. Magnesium fluoride (99.5 nm) was coated on the SiNₓ by vacuum evaporation to form a double antireflection coating layer. Long wavelength internal quantum efficiency (IQE) measurements were performed to characterize the Al-BSF of a finished solar cell. The thickness of the screen-printed aluminum was measured to be about 25 μm by profilometry (Alpha-Step 200) after drying the screen-printed Al. The thickness of the Al-BSF was measured by cross-section Scanning Electron Microscopy (SEM) after etching the heavily p-doped region selectively in 1:3:6 HF:HNO₃:CH₃COOH for 10 seconds [7]. In order to study just the quality of Al-BSF and its impact on the cell performance, photolithography cells were fabricated on FZ wafers with high quality rapid thermal oxide (RTO) on the emitter capped with ZnS/MgF₂ double layers.

Results and Discussion:

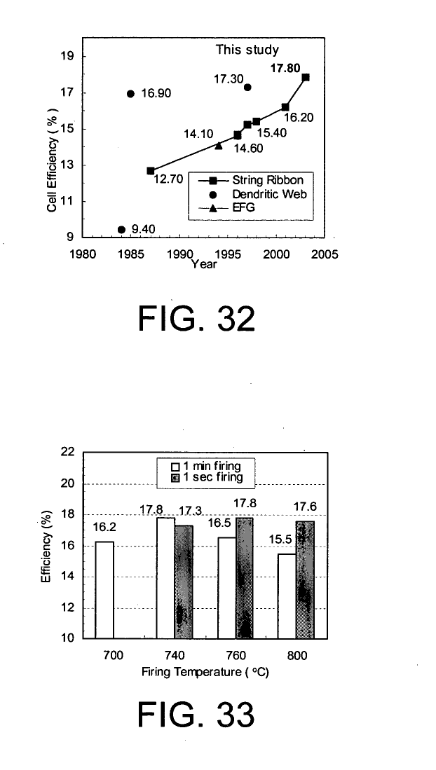

FIG. 32 shows the progress in efficiency of ribbon solar cells with photolithography contacts. Data for Dendritic Web and EFG is limited. The best cells made in this study had NREL verified efficiencies of 17.8%, a new record for String Ribbon.

FIG. 33 shows the efficiencies of String Ribbon cells in this study as a function of firing temperature and time. The cell parameters are summarized in Table 7 with process parameters. A cell with 17.8% efficiency was obtained at 740° C. for 60 second firing time. For a 60-second firing, the efficiency dependence on firing temperature was similar to that of fully screen-printed cells which showed maximum efficiency at 740° C. and rapid decrease in efficiency above 740° C. However, the efficiencies for 1-second firing were found to be less sensitive to the firing temperatures, resulting in an equivalent maximum efficiency of 17.8% at 760° C. It is noteworthy that a very short one second firing gave the same efficiency as 60 seconds.

TABLE 7
Light I-V data for PL cells (masked to 3.8 cm²)
fabricated on String Ribbon Si, measured by National
Renewable Energy Laboratory (NREL).

| Time | Temp | Eff. | V_{oc} | J_{sc} | |
|---|---|---|---|---|---|
| (sec) | (° C.) | (%) | (mV) | (mA/cm²) | FF |
| 60 | 740 | 17.80 | 621.8 | 36.42 | 0.78 |
| 1 | 740 | 17.30 | 619.5 | 35.22 | 0.79 |
| 1 | 760 | 17.80 | 620.0 | 36.81 | 0.78 |
| 1 | 800 | 17.60 | 622.6 | 35.57 | 0.79 |

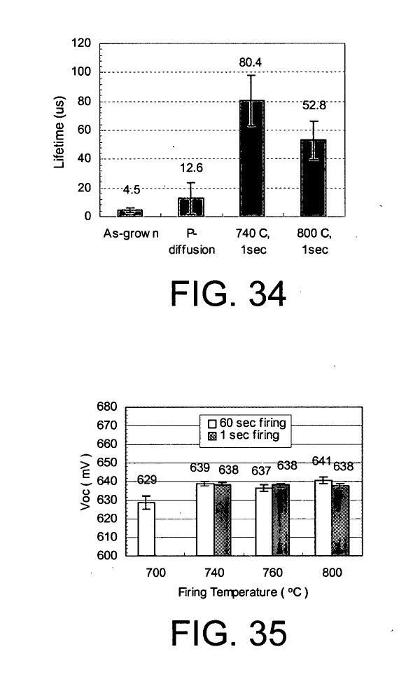

The highest efficiencies in this study are attributed to improvement in bulk lifetime after firing, as shown in FIG. 34. Average bulk lifetime increased to 80.4 μs from 4.5 μs with only 1 second firing. One second firing maintained bulk lifetime over 50 is even at 800° C. whereas bulk lifetime dropped rapidly at the temperatures above 740° C. for 60 second firing. This suggests that hydrogenation of bulk defects takes place in a very short time and the lifetime is determined by the release of hydrogen from the defects. The diffusivity of hydrogen is roughly estimated to be about 9×10⁴ cm²/s, assuming that hydrogen diffuses through a 300 μm thick wafer in 1 second at 740° C. Van Weirengen and Warmoltz measured the hydrogen diffusivity in the temperature range of about 1090 to 1200° C. [8].

$${D}_{H } = 9.4 \times {10}^{- 3} exp ( \frac{- 0.48 eV}{kT} ) {cm}^{2} \text{/} s \qquad ( 1 )$$

Extrapolation of the diffusivity yields a diffusivity of 3.846×10⁻⁵ cm²/s at 740° C. In p-type Si, most of the hydrogen diffuses by rapid interstitial motion at high temperature over 500° C. without any retardation by either acceptor trapping or molecule formation [9]. B. L. Sopori observed that hydrogen can diffuse through the entire wafer after a 10-second annealing of SiNₓ coated wafers at 800° C. in an RTP chamber [10]. The much higher estimated diffusivity than the extrapolated value suggests that hydrogen diffusion may be enhanced by aluminum alloying induced vacancies [11].

In order to study the effects of firing temperature and time on the properties of the Al-BSF, photolithography cells were fabricated on 2 Ωcm FZ wafers with rapid thermal oxide for emitter passivation. For all the firing conditions, the measured Jₒₑ was 2×10⁻¹³ A/cm² without the metal contacts to the emitter. Therefore, the dependence of open circuit voltages on the firing temperature and time in FIG. 35 were governed only by the Al-BSF quality. Note that the improvement in open circuit voltage saturated above firing temperatures of 740° C.

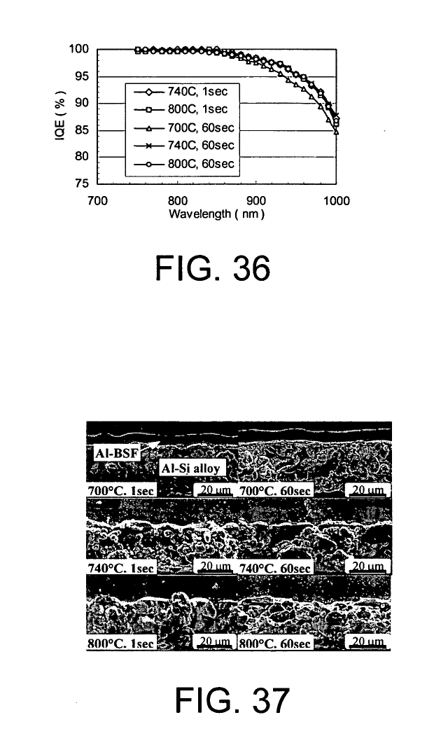

The IQE response of the cells in the range of 750-1,000 nm (FIG. 36) indicates that the Al-BSF quality is not affected appreciably by the firing at temperatures over 740° C. for both 1 and 60 second firing times.

The Al-BSF quality is determined by the junction depth, the doping concentration of the BSF layer, and the uniformity of the p-p⁺ junction. The junction depth can be calculated from the Al—Si phase diagram using the following equation [12],

$${W}_{BSF} = \frac{{t}_{A1} \cdot {ρ}_{A1}}{{ρ}_{Si}} ( \frac{F ( T )}{1 - F ( T )} - \frac{F ( {T}_{o} )}{1 - F ( {T}_{o} )} ) \qquad ( 2 )$$

where t_{Al}, ρ_{Al}, and ρ_{Si} represent the as-deposited Al thickness, the densities of Al and Si respectively, F(T) is the Si atomic weight percentage of the molten phase at the peak alloying temperature, and F(T_{O}) is the Si atomic weight percentage at the eutectic temperature (about 12%). The doping concentration of Al in the BSF is determined by the solid solubility of Al at each temperature as the BSF layer grows from the molten phase during the cooling cycle.

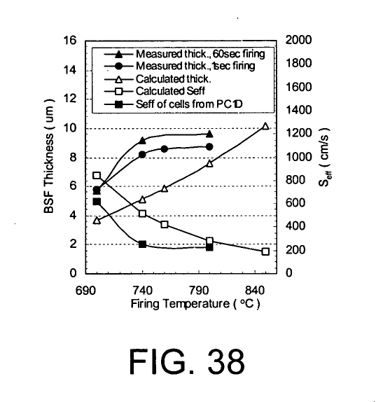

Cross-section SEM images of the layers in the back were taken to measure uniformity and Al-BSF thicknesses after firing. FIG. 37 shows that uniform Al-BSF layers were observed for all the firing temperatures and times due to the high ramp-up rate. The Al-BSF thicknesses measured from SEM images and calculated from equation 2 (ignoring the porosity of screen-printed Al) are shown in FIG. 38. The measured Al-BSF thickness was found to be greater than the calculated thickness using the Al-Si phase diagram at firing temperatures below 800° C. for firing times in the range of 1-60 second. The measured thicknesses tend to match calculated values at higher temperatures. For 1 second firing, the Al-BSF is thicker than the predicted value and exceeds 8 μm at temperatures over 740° C. It is noteworthy that Al—Si alloying and 8 μm thick Si regrowth was accomplished in just a few seconds. It has been reported that the Al-BSF thickness corresponded to the calculated value at typical firing conditions (temperature range of 800-850° C., time >30 seconds). However, relatively short time firing (1 second) at relatively low temperature (<800° C.) is preferred for device performance as well as process speed, as shown earlier in this example. The difference between the measured and calculated Al-BSF thickness from the theoretical value at lower temperatures suggests that thermodynamic equilibrium is not achieved or that the front and back surfaces of the wafers are at different temperatures during RTP firing.

Conclusion:

The industrial processing steps of SiN. AR coating and screen printed Al-BSF have been combined with the laboratory processes for double layer AR coating and photolithography contacts to produce record high 17.8% efficient String Ribbon solar cells.

The bulk lifetime in String Ribbon improved significantly after phosphorus diffusion followed by firing of SiNₓ and Al in RTP. Only 1 second firing at 740° C. increased the bulk lifetime to 80 μs from 4.5 μs, suggesting that release of hydrogen from the defects is the limiting factor for maximum hydrogenation. About 8 μm thick Al-BSF was formed with 1 second firing at temperatures greater than 740° C. and a ramp-up rate of over 50° C./sec. SEM analysis confirmed that the measured Al-BSF thickness was greater than the calculated thickness at firing temperatures lower than 800° C., suggesting that thermodynamic equilibrium may not be achieved during short and rapid firing.

### REFERENCES

[1] V. Yelundur, A. Rohatgi, J-W. Jeong, “PECVD SiNₓ induced hydrogen passivation in String Ribbon silicon”, Proceedings of the 28th Photovoltaic Specialists Conference, (IEEE, Anchorage, 2000) p. 91.
[2] J. I. Hanoka, “An overview of silicon ribbon growth technology”, Sol. Energy Mater. & Sol. Cells, 65, 231(2001).
[3] G. Hahn, A. M. Gabor, “16% efficiency on encapsulated large area screen printed string ribbon cell”, The Third World Conference on Photovoltaic Energy Conversion, (Osaka, 2003), in press.
[4] V. Yelundur, A. Rohatgi, J. W. Jeong, J. Hanoka, “Improved String Ribbon silicon solar cell performance by rapid thermal firing of screen-printed contacts”, IEEE Tran. on Elec. Dev., 49, no. 8, 1405(2002).
[5] V. Meemongkolkiat, M. Hilali, A. Rohatgi, “Investigation of RTP and belt fired screen printed Al-BSF on textured and planar back surfaces of silicon solar cells”, The Third World Conference on Photovoltaic Energy Conversion, (Osaka, 2003), in press.
[6] A. Rohatgi, V. Yelundur, J-W. Jeong, D. S. Kim, A. M. Gabor, “Implementation of rapid thermal processing to achieve greater than 15% efficient screen-printed ribbon silicon solar cells”, The Third World Conference on Photovoltaic Energy Conversion, (Osaka, 2003), in press.
[7] W. R. Runyan, Semiconductor Measurements and Instrumentation (McGraw-Hill: New York), 1975.
[8] A. Van Wieringen and N. Warmoltz, Physica (Netherlands), 22, 849(1956).
[9] J. Pearton, W. Corbett and M. Stavola, Hydrogen in crystalline semiconductors (Springer-Verlag Heidelberg New York), 1991.
[10] B. L. Sopori, Y. Zhang, and R. Reedy, “H diffusion for impurity and defect passivation: a physical model for solar cell processing”, Proceedings of the 29th Photovoltaic Specialists Conference (IEEE, New Orleans, 2002) p. 222.
[11] J-W. Jeong, M. D. Rosenblum, J. P. Kalejs, and A. Rohatgi, “Hydrogenation of defects in edge-defined film-fed grown aluminum-enhanced plasma enhanced chemical vapor deposited silicon nitride multicrystalline silicon”, J. Appl. Phys., 87, no. 10, 7551(2000).
[12] J. D. Alamo, J. Eguren, and A. Luque, “Operating limits of Al-alloyed high-low junctions for BSF solar cells”, Solid-State Electron., 24, p. 415(1981).

### EXAMPLE 7

Now having described the embodiments of the nanostructure in general, Example 7 describes some embodiments of the nanostructure and uses thereof. The following is a non-limiting illustrative example of an embodiment of the present disclosure that is described in more detail in K. Nakayashiki, V. Meemongkolkiat, and A. Rohatgi “High Efficiency Screen-printed EFG Si Solar Cells Through Rapid Thermal Processing-induced Bulk Lifetime Enhancement,” Submitted, Progress in Photovoltaics 2004, which is incorporated herein by reference. This example is not intended to limit the scope of any embodiment of the present disclosure, but rather is intended to provide some experimental conditions and results. Therefore, one skilled in the art would understand that many experimental conditions can be modified, but it is intended that these modifications be within the scope of the embodiments of the present disclosure.

Introduction:

This example shows that one second (1 s) firing of Si solar cells with screen-printed Al on the back and SiNₓ anti-reflection coating on the front can produce a high quality Al-doped back surface field (Al-BSF) and can significantly enhance SiNₓ-induced defect hydrogenation in the bulk Si. Open-circuit voltage, internal quantum efficiency measurements, and cross-sectional scanning electron microscopy pictures on float-zone silicon cells revealed that 1 s firing in rapid thermal processing at 750° C. produces just as good a BSF as 60 s firing, indicating that the quality of Al-BSF region is not a strong function of RTP firing time at 750° C. Analysis of edge-defined film-fed grown (EFG) Si cells showed that short term firing is much more effective in improving the hydrogen passivation of bulk defects in EFG Si. Average minority carrier lifetime in EFG wafers improved from about 3 μs to about 33 μs by 60 μs firing but reached as high as 95 μs due to 1 s firing, resulting in 15.6% efficient screen-printed cells on EFG Si.

Experimental:

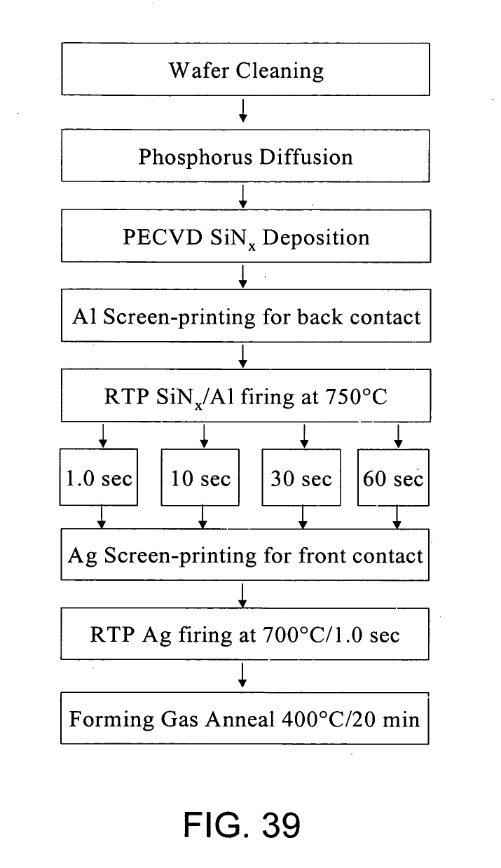

In this study, simple n⁺-p-p⁺ solar cells were fabricated with screen-printed Al on the back and screen-printed Ag grid on the front. Each wafer had nine 4 cm² (2×2 cm) solar cells, which were isolated with a dicing saw before testing. The EFG Si had a resistivity of 2 to 3 Ω-cm and a thickness of about 300 μm while the FZ wafers were 2.4 Ω-cm with a thickness of about 300 μm. After the initial etching and cleaning, the wafers were phosphorus diffused in a POCl₃ furnace to obtain an emitter sheet resistance of 45±5 Ω/sq. A SiNₓ AR coating with a thickness of 750±50 Å and refraction index of 2.0 was deposited in a low-frequency PECVD reactor with N₂ pretreatment. After the visual inspection, the Al paste (Ferro FX 53-038) was screen-printed on the back and fired in a RTP system (AG Associates 610) at 750° C. (firing step #1) with holding time-periods of 1, 10, 30, and 60 s in conjunction with a temperature ramp-up rate of about 100° C./s and ramp-down rate of about 50° C./s.⁷ The temperature was measured by a thermocouple which was mounted on the front surface with SiNₓ coating. The Ag grid was screen-printed (Ferro 3349) and fired in the RTP system at 700° C. for 1 s, using similar ramp-up and ramp-down rates (firing step #2). A 400° C./20 min. Forming Gas Anneal was performed at the end to ensure good ohmic contacts. FIG. 39 describes various process sequences used in this study. Eighteen cells were fabricated for each scheme to account for the statistical and spatial variation in EFG Si cells. After the cell fabrication, illuminated and dark current-voltage (1-V) measurements were performed to extract the solar cell performance parameters. Cross-sectional Scanning Electron Microscopy (SEM) was used to investigate the uniformity of Al-BSF region. Prior to the SEM measurements, samples were broken along the crystal direction followed by etching in 1:3:6 HF:HNO₃:CH₃COOH. The purpose of this etching is to delineate the Al-BSF (heavily p-doped) from the bulk (lightly p-doped) region.⁸ The quasi-steady-state photoconductance (QSSPC) technique was used for the minority carrier lifetime measurements, in addition to the I-V and internal quantum efficiency (IQE) measurements. The QSSPC lifetime measurements were performed at several different locations on each sample using iodine/methanol solution for surface passivation. The average lifetime values were determined at an injection level of 1.0×10¹⁵ cm⁻³.⁹

Results and Discussion:

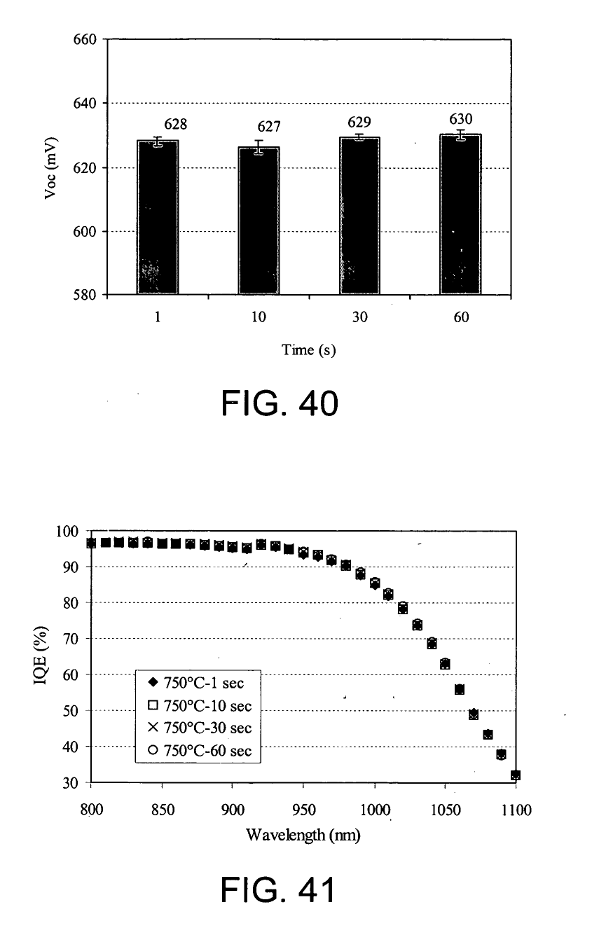

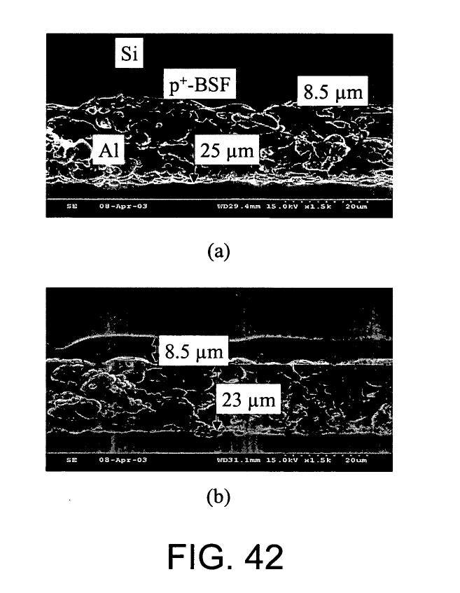

The open-circuit voltage (V_{OC}) of a solar cell is a strong function of the minority carrier lifetime as well as the quality of the Al-BSF region. The V_{OC} might also be influenced by the inhomogeneous material quality. FIGS. 40 and 43 and 44 show the average values and the scatter in V_{OC} of the FZ and EFG Si cells as a function of Al-BSF firing time from 1 to 60 s. FIG. 40 shows that the spread in V_{OC} is only about 3 mV for the FZ Si cells, indicating that 1 s firing is able to achieve a uniform Al-BSF with a quality comparable to the prolonged firing. Notice that FZ material with ≧200 bs bulk lifetime was used intentionally to make V_{OC} more sensitive to the Al-BSF quality and less dependent on the bulk lifetime. The long wavelength IQE analysis was performed on the FZ Si cells to verify the quality of Al-BSF region for each scheme. FIG. 41 shows that the IQE in the long wavelength region (800-1100 nm) was essentially independent of SiNₓ/Al firing time in the range of 1-60 s at 750° C. (firing step #1). The cross-sectional SEM analysis was performed for each scheme to investigate the uniformity and thickness of the Al-BSF region. FIG. 42 shows the SEM pictures of the Al-BSF regions in the FZ samples subjected to 1 and 60 s firing at 750° C. In both cases, the Al-BSF region was quite uniform with an approximate thickness of about 8.5 μm. The Al-BSF pictures, V_{OC}, and the IQE (FIGS. 40 and 42) demonstrate that the thickness, uniformity, and quality of Al-BSF region are not a strong function of RTP firing time in the range of 1-60 s. This is important because, as shown below, 1 s firing is much more effective for defect hydrogenation.

The EFG Si cells were analyzed to investigate the effect of firing time on defect hydrogenation. It is known that the annealing of the SiNₓ film injects atomic hydrogen into the bulk Si and passivates defects. However, hydrogen can also evolve out of these defects at or below 750° C.² Thus the challenge is to find the optimum firing condition at which the competition between supply and dissociation of hydrogen results in maximum retention of atomic hydrogen at defects.

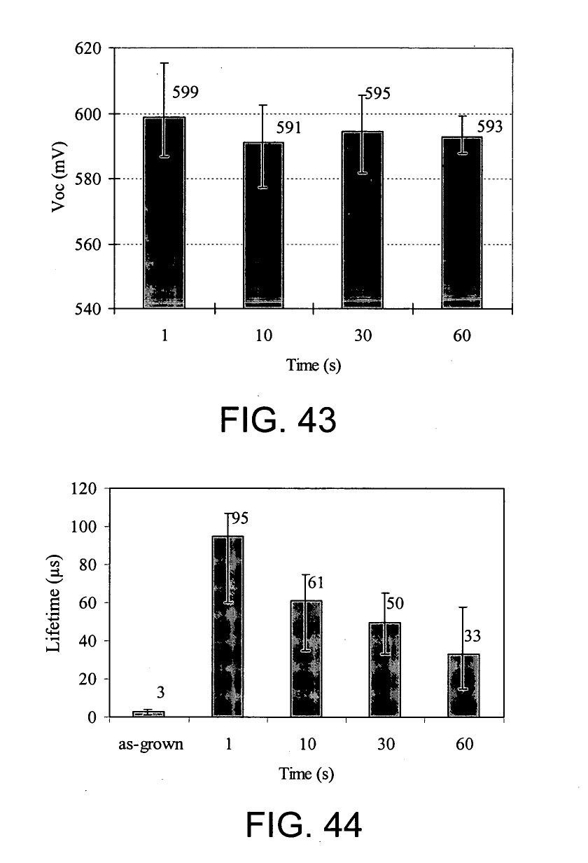

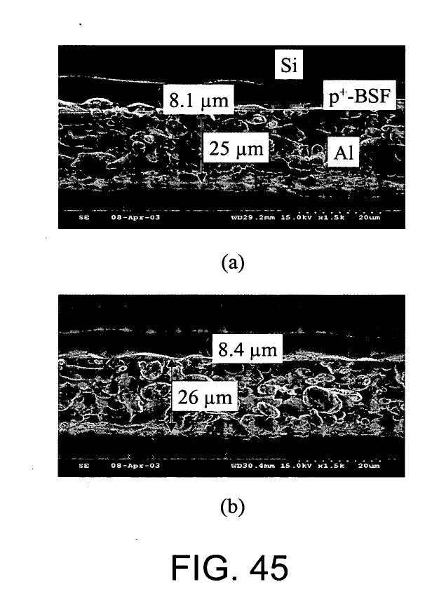

FIG. 43 shows the V_{oc} of the EFG Si cells as a function of firing time. Contrary to the FZ Si cells, the 1 s firing process for EFG Si gave the highest average V_{OC} of 599 mV with the maximum value of 613 mV. The V_{OC} values declined with the increase in firing time from 1 to 60 s except for the 10 s firing case. This discrepancy is probably due to the fact that V_{OC} is not only a function of bulk lifetime but also parameters including resistivity, back surface recombination velocity (BSRV), and defect distribution, which can be different and non-uniform in different EFG Si samples. Since FZ samples revealed no difference in V_{OC} or the Al-BSF quality as a function of firing time, the V_{OC} difference in the case of EFG Si cells is largely attributed to the difference in bulk lifetime. To verify this hypothesis, QSSPC lifetime measurements were performed on these samples after etching the cell down to bare Si by removing the metal contacts, SiNₓ AR coating, n⁺ emitter, and Al-BSF. FIG. 44 clearly shows that the minority carrier lifetime decreases monotonically with the increase in firing time. Surprisingly, the 1 s Al-BSF firing process gave the highest lifetime of 95 μs, which decreased to 33 μs for 60 s firing. This suggests that the supply of hydrogen and passivation of defects are very fast processes and prolonged annealing (>1 s) causes more dehydrogenation due to the dissociation of hydrogen from the defects. FIG. 45 shows the cross-sectional SEM pictures of Al-BSF regions in EFG Si cells fabricated with 1 and 60 s firing. Again, as found in the FZ Si cells, the Al-BSF thickness in EFG Si is not a function of Al-BSF firing time, supporting that higher V_{OC} for shorter firing time in EFG Si must be due to the enhanced hydrogenation or reduced dehydrogenation from the defects.

It has been suggested in the literature that the release of hydrogen from the SiNₓ film is very rapid initially and then slows down.^{10,11} This implies that hydrogen supply decreases rapidly with time while dehydrogenation of defects continues. As a result, shorter firing time is able to retain more hydrogen atoms at the defects to produce high bulk lifetime. In order to prove rapid dehydrogenation at 750° C., a two-step experiment was performed. First, the SiNₓ layer and metal contacts were removed after the hydrogenation step (750° C./1 s) to eliminate further supply of hydrogen. Measured bulk lifetime in this sample after the first step was 85 μs. Then the sample was reannealed at 750° C. in the RTP system to drive the hydrogen out of the defects. FZ Si sample was also annealed in the RTP system to verify that the observed change in carrier lifetime is due to the hydrogen out-diffusion and not due to some contamination during the heat treatment. It was found that it only took 2 s to reduce the bulk lifetime in EFG Si from 85 μs to 10 μs while no appreciable change in carrier lifetime was observed in FZ Si which remained at about 270 Us after a 750° C./2 s RTP annealing. This explains why prolonged firing at 750° C. is detrimental for bulk lifetime in EFG Si. This result also suggests that the single-step firing might be better than the two-step firing for the hydrogen retention at defect sites because second firing step may cause some dehydrogenation.

Lighted I-V data for the FZ Si cells in Table 8 show that the spread in V_{oc} was only ≦3 mV and J_{SC} was ≦0.2 mA/cm², resulting in an insignificant difference in cell efficiency (≦0.2%) as a function of Al-BSF firing time. In addition, the average and the best values of the cell parameters were virtually identical for FZ Si cells. Average fill factor decreased for shorter firing time in this study because Ag grid contact firing was optimized for a 60 s Al-BSF firing cycle using FZ Si cells. Shorter firing time for the same firing temperature may introduce higher series resistance. Table 9 shows the average and the best values of EFG Si cell parameters for each firing time. The 1 s firing time produced the best cell performance with an average V_{OC} of 599 mV and the best V_{OC} of 613 mV. Unlike the FZ Si cells, the difference in the average V_{OC} values was about 6 mV for 1 and 60 s firing times. The average cell efficiencies for 10 and 30 s firing are lower than for the 60 s firing time due to lower fill factor values. Table 9 also shows high J_{SC} values for 10 and 30 s firing case. This is probably due to the non-uniform resistivity distributions of EFG Si. These parameters were averaged over two wafers or eighteen cells.

TABLE 8
Average values of FZ Si cell parameters for each scheme

| BSF firing | V_{oc} | J_{sc} | | |
|---|---|---|---|---|
| time (s) | (mV) | (mA/cm²) | FF | Eff.(%) |
| 1 | 628 | 34.3 | 0.743 | 16.1 |
| 10 | 627 | 34.2 | 0.754 | 16.2 |
| 30 | 629 | 34.2 | 0.757 | 16.2 |
| 60 | 630 | 34.1 | 0.760 | 16.3 |

TABLE 9
Average and the highest values of
parameters of EFG Si on each scheme

| | | | | |
|---|---|---|---|---|
| | V_{oc} | J_{sc} | | |
| Avg./High | (mV) | (mA/cm²) | FF | Eff.(%) |

1 s firing

| | | | | |
|---|---|---|---|---|
| average | 599 | 32.5 | 0.764 | 14.9 |
| highest | 613 | 33.0 | 0.769 | 15.6 |

10 s firing

| | | | | |
|---|---|---|---|---|
| average | 591 | 32.8 | 0.749 | 14.5 |
| highest | 602 | 33.1 | 0.764 | 15.2 |

30 s firing

| | | | | |
|---|---|---|---|---|
| average | 595 | 32.7 | 0.742 | 14.4 |
| highest | 604 | 33.1 | 0.756 | 15.1 |

60 s firing

| | | | | |
|---|---|---|---|---|
| average | 593 | 32.1 | 0.767 | 14.6 |
| highest | 599 | 32.2 | 0.770 | 14.8 |

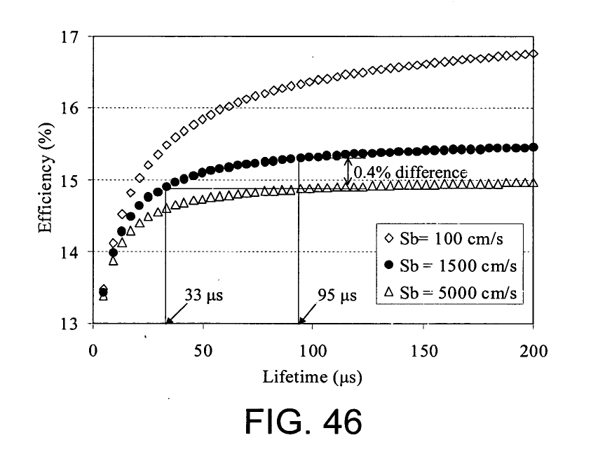

Next, device simulations were performed using the PC1D software in order to establish that the efficiency difference in EFG Si cells is primarily due to the observed lifetime enhancement from 33 μs (for 60 s firing) to 95 μs (for 1 s firing). 12 Table 10 shows the key input parameters used to perform the simulation for screen-printed devices with fill factor of 0.77. FIG. 46 shows the calculated effect of bulk lifetime and BSRV on the efficiency of the screen-printed cells. Device simulations indicate that the 15.3% efficient EFG Si cells with a bulk lifetime of 95 μs must have an effective BSRV value of 1,500 cm/s. It is also important to realize that the BSRV may not be spatially uniform over the cell area due to defect non-uniformity in EFG Si. Therefore, 1,500 cm/s must be viewed as an effective BSRV value. The BSRV value in EFG Si cells for the same Al-BSF process has been shown to be much higher than in FZ Si cells possibly due to the presence of defects at the p-p⁺ interface. Simulations in FIG. 46 also reveal that at high BSRV value of 1,500 cm/s, lifetime enhancement from 33 μs to 95 μs for this cell design can only produce about 0.4% increase in the absolute efficiency, which is close to what was observed (about 0.3%) in Table 9. Model calculation in FIG. 46 also revealed that for a bulk lifetime change from 33 μs to 95 μs, V_{oc} and J_{sc} change by only 7 mV and 0.4 mA/cm², respectively, for a high BSRV value of 1,500 cm/s. This is in general agreement with the explained data in Table 9. Thus, 1 s RTP firing of SiNₓ/Al enhances throughput and bulk lifetime without sacrificing the Al-BSF quality.

TABLE 10
Material and device parameters used for screen-printed cell simulation

| Parameters | Values | |
|---|---|---|
| Resistivity | 3.0 | Ω-cm |
| Thickness | 300 | μm |
| Sheet Resistance | 45 | Ω/sq. |
| R_{S} | 0.9 | Ω-cm² |
| R_{Sh} | 10,000 | Ω-cm² |
| J₀₂ | 5.0 | nA/cm² |
| Front SRV* | 35,000 | cm/s |

| | |
|---|---|
| Back SRV* (S_{b}) | Variable |
| SiNₓ AR Coating | 780 Å, index = 2.0 |
| Ag grid coverage | 7% |

*SRV—surface recombination velocity

Conclusion:

It is found that the formation of Al-BSF region is not a strong function of firing time in the range of 1-60 s at 750° C. The cross-sectional SEM pictures of the FZ and EFG samples show that there is virtually no difference in the Al-BSF thickness and its uniformity between 1 and 60 s RTP Al-BSF firing. As a result, no appreciable difference in efficiencies of FZ Si cells was observed as a function of back contact firing time. However, in the case of the EFG Si cells, change in firing condition significantly influenced the SiNₓ-induced hydrogen passivation, with one second SiNₓ/Al-BSF firing providing much greater minority carrier lifetime enhancement than 60 s firing. This is due to the competition between the supply and evolution of hydrogen to and from the defects, respectively. These results suggest that hydrogen diffuses very rapidly (≦1 s) into the Si bulk to passivate defects, but evolution of hydrogen from the defects is also very rapid. It is shown that the lifetime decreases from 85 to 10 μs in 2 s at 750° C. in the absence of hydrogen supply. If hydrogen supply decreases with time, as suggested in the literature, retention of hydrogen at defects becomes more critical. As a result, 1 s hydrogenation at 750° C. is more effective than 60 seconds. By taking advantage of this very short firing cycle, which does not degrade Al-BSF and gives higher bulk lifetime, and high efficiency (15.6%) screen-printed EFG Si cells were achieved.

### REFERENCES

¹ Bell R O, Kalejs J P. Growth of silicon sheet for photovoltaic applications. Journal of Materials Research 1998; 13: 2732-2739.
² Jeong J, Rohatgi A, Rosenblum M D, Kalejs J P. Lifetime Enhancement in EFG Multicrystalline Silicon. Proc. 28th IEEE Photovoltaic Specialists Conference, Anchorage, AK, 2000; 83-86.
³ Doshi P, Rohatgi A. 18% Efficient Silicon Photovoltaic Devices by Rapid Thermal Diffusion and Oxidation. IEEE Transactions on Electron Devices 1998; 45: 1710-1716.
⁴ Rohatgi A, Narasimha S, Ebong A, Doshi P. Understanding and Implementation of Rapid Thermal Technologies for High-Efficiency Silicon Solar Cells. IEEE Transactions on Electron Devices 1999; 46: 1970-1977.
⁵ Jeong J, Rohatgi A, Yelundur V, Ebong A, Rosenblum M D, Kalejs J P. Enhanced silicon solar cell performance by rapid thermal firing of screen-printed metals. IEEE Transaction of Electron Devices 2001; 48: 2836-2841.
⁶ Plekhanov P S, Negoita M D, Tan T Y. Effect of Al-induced gettering and back surface field on the efficiency of Si solar cells. Journal of Applied Physics 2001; 90: 5388-5394.
⁷ Jeong J, Cho Y H, Rohatgi A, Rosenblum M D, Bathey B R, Kalejs J P. Rapid thermal processing to enhance PECVD SiN-induced hydrogenation in high-efficiency EFG silicon solar cells. Proc. 29th IEEE Photovoltaic Specialists Conference, New Orleans, La., 2002; 250-253.
⁸ Runyan W R. Semiconductor Measurements and Instrumentation. McGraw-Hill: New York, 1975; 187-216.
⁹ Macdonald D, Cuevas A. Trapping of minority carriers in multicrystalline silicon. Applied Physics Letters 1999; 74: 1710-1712.
¹⁰ Boehme C, Lucovsky G. Dissociation reactions of hydrogen in remote plasma-enhanced chemical vapor deposition silicon nitride. Journal of Vacuum Science and Technology A 2001; 19: 2622-2628.
¹¹ Gadiyak G V, Gadiyak V G, Kosinova M L, Salman E G. Model and computer simulation results of defect transformation and decomposition of SiNₓ:H films during high temperature treatment. Thin Solid Films 1998; 335: 19-26.
¹² Basore P A, Clugston D A. PC1D version 4 for Windows: from analysis to design. Proc. 25th IEEE Photovoltaic Specialists Conference, Washington D.C., 1996; 377-381.
¹³ Meemongkolkiat V, Hilali M, Nakayashiki K, Rohatgi A. Process and Material Dependence of Al-BSF in Crystalline Si Solar Cells. Technical Digest 14^{th} International Photovoltaic Science and Engineering Conference, Bangkok, Thailand, 2004; 401-402.

1. A device, comprising:
a co-fired p-type silicon substrate having a top-side and a back-side, wherein the bulk lifetime is about 20 to 125 μs;
an n⁺ layer formed on the top-side of the p-silicon substrate;
a silicon nitride anti-reflective (AR) layer positioned on the top-side of the n⁺ layer;
a plurality of Ag contacts positioned on portions of the silicon nitride AR layer, wherein the Ag contacts are in electronic communication with the n⁺ layer;
an uniform Al back-surface field (BSF) layer having a top-side and a back-side, the top-side of the Al BSF layer being positioned on the back-side of the p-silicon substrate; and
an Al contact layer positioned on the back-side of the Al BSF layer,
wherein the device has a fill factor (FF) of about 0.75 to 0.85, an open circuit voltage (V_{OC}) of about 600 to 650 mV, and a short circuit current density (J_{SC}) of about 28 to 36 mA/cm².

2. The device of claim 1, further comprising a series resistance (R_{S}) of about 0.01 to 1 Ω-cm², a shunt resistance of about 1000 to 5000 kΩ, a junction leakage current (J_{O2}) of about 1 to 10 nA/cm², and a contact resistance (ρ_{c}) of about 0.01 to 3 mΩ-cm².

3. The device of claim 1, wherein the co-fired p-silicon substrate has a bulk lifetime of 75 to 125 μs.

4. The device of claim 1, further comprising a back surface recombination velocity (BSRV) of about 1 to 1000 cm/s.

5. The device of claim 1, wherein the co-fired p-silicon substrate is selected from edge defined fed grown (EFG) Si ribbon, string Si ribbon, float-zone (FZ) Si, Cz Si, and multi-crystalline silicon (mc-Si).

6. The device of claim 1, wherein the n⁺-layer is about 55 to 120 Ω/sq emitter.

7. The device of claim 1, wherein the n⁺-layer is about an 60 to 120 Ω/sq emitter.

8. The device of claim 1, wherein the n⁺ layer is about an 65 to 120 Ω/sq emitter.

9. The device of claim 1, wherein the n⁺ layer is about an 70 to 120 Ω/sq emitter.

10. The device of claim 1, wherein the n⁺ layer is about an 75 to 120 Ω/sq emitter.

11. The device of claim 1, wherein the n⁺ layer is about an 80 to 120 Ω/sq emitter.

12. The device of claim 1, wherein the n⁺ layer is about an 85 to 120 Ω/sq emitter.

13. The device of claim 1, wherein the n⁺ layer is about an 90 to 120 Ω/sq emitter.

14. The device of claim 1, wherein the n⁺ layer is about an 95 to 120 Ω/sq emitter.

15. The device of claim 1, wherein the n⁺ layer is about an 100 to 120 Ω/sq emitter.

16. The device of claim 1, wherein the co-fired p-type silicon substrate has a thickness of about 150 to 300 Ωm, the n⁺ layer has a thickness of about 0.3 to 0.5 μm, the silicon nitride anti-reflective (AR) layer has a thickness of about 700 to 800 Å, the Ag contacts have a thickness of about 10 to 15 μm, the Al back-surface field (BSF) layer has a thickness of about 5 to 15 μm, and the Al contact layer has a thickness of about 20 μm to 40 μm.

17. The device of claim 1, further comprising a FF of about 0.78 to 0.81, an V_{OC} of about 640 to 650 mV, a J_{SC} of about 34 to 36 mA/cm², and a BSRV of about 200 to 900 cm/s.

18. A solar cell structure, comprising:
a co-fired p-type silicon substrate having a top-side and a back-side, wherein the bulk lifetime is about 75 to 125 μs;
a n⁺ layer having a top-side and a back-side, the n⁺ layer being formed on the top-side of the p-silicon substrate, wherein the n⁺ is a about 90 to 120 Ω/sq emitter;
a silicon nitride anti-reflective (AR) layer positioned on the top-side of the n⁺ layer;
a plurality of Ag contacts positioned on portions of the silicon nitride AR layer, wherein the Ag contacts are in electronic communication with the n⁺ layer;
an Al back surface field (BSF) layer having a top-side and a back-side, the Al BSF layer being positioned on the back-side of the co-fired p-silicon substrate on the back-side of the p-type silicon substrate as the n⁺ layer; and
an Al contact layer positioned on the back-side of the Al back-surface field (BSF) layer,
wherein the solar cell has a fill factor (FF) of about 0.78 to 0.81, an open circuit voltage (V_{OC}) of about 640 to 650 mV, a short circuit current density (J_{SC}) of about 34 to 36 mA/cm², a series resistance (R_{S}) of about 0.8 to 1 Ω-cm², a shunt resistance of about 1000 to 2000 kΩ, a junction leakage current of about 7 to 10 nA/cm², and a back surface recombinant velocity (BSRV) of about 200 to 900 cm/s, and wherein the contact resistance (ρ_{c}) of the Ag contacts with the n⁺ layer is about 1.5 to 2 Ω-cm².

19. A method for fabricating a silicon solar cell structure comprising:
providing a p-silicon substrate having a top-side and a back-side;
forming a n⁺ layer on the top-side of the p-silicon substrate;
forming a silicon nitride anti-reflective (AR) layer on the top-side of the n⁺ layer;
forming Ag contacts on the silicon nitride anti-reflective (AR) layer using a screen-printing technique;
forming an Al contact layer on the back-side of the p-silicon substrate using a screen-printing technique;
co-firing of the p-silicon substrate having the n⁺ layer, silicon nitride anti-reflective (AR) layer, Ag metal contacts, and Al contact layer; and
forming a co-fired silicon solar cell structure, wherein the Ag contacts are in electrical communication with the n⁺ layer, wherein an Al back surface field layer (BSF) is formed, and wherein the silicon solar cell has a fill factor of about 0.75 to 0.85, a V_{OC} of about 550 to 650 mV, and a J_{SC} of about 28 to 36 mA/cm².

20. The method of claim 19, wherein the p-silicon substrate samples are POCl₃ diffused to form the n⁺ layer.

21. The method of claim 19, further comprising, positioning the silicon nitride layer in a low frequency plasma enhanced chemical vapor deposition (PECVD) reactor on the n⁺ layer.

22. The method of claim 21, wherein NH₃ and SiH₄ gases are used in the PECVD reactor to form the silicon nitride layer.

23. The method of claim 19, wherein the silicon nitride layer is positioned at about 750 to 800 Å, at a low frequency range of about 50-100 kHz and at about 400 to 500° C.

24. The method of claim 19, wherein an Al paste is screen-printed on the back-side of the p-silicon substrate and dried at about 150 to 250° C.

25. The method of claim 19, further comprising an Ag metal grip interconnecting the Ag contacts.

26. The method of claim 19, wherein forming the silicon solar cell structure includes a co-firing process; wherein the co-firing process includes
heating the belt furnace at a rate of about 50 to 100° C./second to a temperature of about 700 to 900° C.;
holding the temperature in the belt furnace at about 700 to 900° C. for about 1 to 5 seconds; and
reducing the temperature in the belt furnace at a rate of about 50 to 100° C./second.

27. The method of claim 26, wherein heating the belt furnace includes heating the belt furnace at a rate of about 50 to 80° C./s to a temperature of about 700 to 900° C.

28. The method of claim 26, wherein heating the belt furnace includes heating the belt furnace at a rate of about 50 to 60° C./s to a temperature of about 700 to 900° C.

29. The method of claim 26, wherein holding the temperature includes holding the temperature in the belt furnace at about 750 to 850° C. for about 1 to 5 seconds.

30. The method of claim 26, wherein holding the temperature includes holding the temperature in the belt furnace at about 740 to 780° C. for about 1 to 3 seconds.

31. The method of claim 26, wherein reducing the temperature includes reducing the temperature in the belt furnace at a rate of about 50 to 80° C./second.

32. The method of claim 26, wherein reducing the temperature includes reducing the temperature in the belt furnace at a rate of about 50 to 60° C./second.

33. A method for co-firing a silicon solar cell, comprising:
providing a silicon solar cell structure, wherein the silicon solar cell structure comprises:
a p-silicon substrate having a top-side and a back-side;
a n⁺ layer on the top-side of the p-silicon substrate;
a silicon nitride anti-reflective (AR) layer on the top-side of the n⁺ layer;
an Ag contacts on the silicon nitride anti-reflective (AR) layer using a screen-printing technique;
an Al contact layer on the back-side of the p-silicon substrate using a screen-printing technique;
disposing the the p-silicon substrate having the n⁺ layer, silicon nitride anti-reflective (AR) layer, Ag metal grid, and Al contact layer, into a belt furnace;
heating the belt furnace at a rate of about 50 to 100° C./second to a temperature of about 700 to 900° C.;
holding the temperature in the belt furnace at about 700 to 900° C. for about 1 to 5 seconds; and
reducing the temperature in the belt furnace at a rate of about 50 to 100° C./second.

34. The method of claim 33, wherein heating the belt furnace includes heating the belt furnace at a rate of about 50 to 80° C./s to a temperature of about 700 to 900° C.

35. The method of claim 33, wherein heating the belt furnace includes heating the belt furnace at a rate of about 50 to 60° C./s to a temperature of about 700 to 900° C.

36. The method of claim 33, wherein holding the temperature includes holding the temperature in the belt furnace at about 750 to 850° C. for about 1 to 5 seconds.

37. The method of claim 33, wherein holding the temperature includes holding the temperature in the belt furnace at about 740 to 780° C. for about 1 to 5 seconds.

38. The method of claim 33, wherein reducing the temperature includes reducing the temperature in the belt furnace at a rate of about 50 to 80° C./second.

39. The method of claim 33, wherein reducing the temperature includes reducing the temperature in the belt furnace at a rate of about 50 to 60° C./second.

40. A product formed by the process of claim 33.
